(19) United States
(12) Patent Application Publication
(10) Pub. No.: US 2018/0060448 A1
(43) Pub. Date: Mar. 1, 2018

(54) COMPUTER AND METHOD OF CREATING GRAPH DATA

(71) Applicant: Hitachi, Ltd., Tokyo (JP)

(72) Inventor: Atsushi MIYAMOTO, Tokyo (JP)

(73) Assignee: Hitachi, Ltd., Tokyo (JP)

(21) Appl. No.: 15/556,626

(22) PCT Filed: Mar. 27, 2015
(86) PCT No.: PCT/JP2015/059537

§ 371 Date: Sep. 8, 2017

(51) Int. Cl. G06F 17/30; G06K 9/62; H03M 7/30

(52) U.S. Cl. CPC G06F 17/30958; G06F 17/30312; H03M 7/30; G06F 17/30598; G06K 9/6218; G06F 17/30539

(57) ABSTRACT

Disclosed is a computer configured to create graph data having a vertex corresponding to a single index, an edge that links a pair of the vertices having a correlation, and an edge weight as a value of the element from the correlation matrix data having correlation values between a plurality of indices as elements, in which the correlation matrix data is acquired from the storage unit, elements of a spanning tree formed by linking vertices corresponding to indices included in the acquired correlation matrix data and an element having a value equal to or greater than a predetermined threshold value are detected, and the graph data is created on the basis of the detected elements.

### TECHNICAL FIELD

The present invention relates to a computer and a method of creating graph data in a big data analysis using graph data.

### BACKGROUND ART

Big data analyses in which useful information is extracted from a large amount of data (big data) obtained from the Web or sensors have attracted attention. In the big data analyses, data analysis techniques such as statistics, pattern recognition, and artificial intelligence are applied to a large amount of data in combination, so that correlations and patterns between items hidden in the data are detected as knowledge. Since potential information hidden in data is mined, the big data analysis is also called “data mining.” Techniques of the big data analysis include, for example, a correlation analysis, a regression analysis, and a principal component analysis in statistics, pattern recognition, machine learning in artificial intelligence, clustering, and the like.

In order to obtain useful information in the big data analysis, it is necessary to analyze a significantly large amount of data. However, as the data amount increases, and the data analysis techniques are improved, a processing time and a memory consumption increase, and this is an excessive burden to hardware resources disadvantageously. In particular, in the field of social sciences, it is demanded to effectively output a result while maintaining necessary accuracy using limited hardware resources within a limited time.

For example, in a basic correlation analysis and principal component analysis as the statistical data analysis techniques, indices (such as a feature amount or an item) are created from the big data, and a correlation between the indices is obtained. In this case, assuming that the number of indices is set to “m,” the correlation is expressed as a correlation matrix having “m” rows and “m” columns, and the correlation analysis and the principal component analysis are executed by computing the correlation matrix. However, the matrix computation necessitates accumulation of data for overall elements in order to execute a computation process for overall elements. For this reason, in a big data handling system, efficiency is degraded from the viewpoints of the computation load and the memory consumption. As a result, accumulation and computation of the big data (expressed as the correlation matrices) consisting of a large number of indices are excessive burdens to hardware resources.

A method of compressing big data and optimizing the processing is discussed in US 2001/0,011,958 A (Patent Document 1). In Patent Document 1, for the purposes of data accumulation and communication cost reduction, big data are converted, compressed, and reorganized on the basis of a multivariable data analysis technique. The method discussed in Patent Document 1 includes a step of obtaining a m×m correlation matrix from original data having “n” columns and “m” items by assuming the number of samples set to “n” and the number of indices set to “m,” a step of obtaining an eigenvalue and an eigenvector of the correlation matrix, a step of obtaining a factor loading matrix from the eigenvalue and the eigenvector, a step of creating a random matrix having “1” columns and “p” rows, a step of obtaining an intermediate data matrix having “1” columns and “m” rows by multiplexing the random matrix by the factor loading matrix, and a step of obtaining a reorganized data matrix having “1” columns and “m” rows by scaling the intermediate data matrix. In the technique of Patent Document 1, by allowing data reorganization, it is possible to reduce cost for communication and data accumulation.

### CITATION LIST

### Patent Document

Patent Document 1: US 2001/0,011,958 A

### SUMMARY OF THE INVENTION

### Problems to be Solved by the Invention

In the method of Patent Document 1, in order to reduce cost for data accumulation and communication, a predominant object is to compress the number of samples “n” of the original data. Therefore, the method of Patent Document 1 fails to sufficiently consider constraints on hardware resources in the analysis process. In addition, in the method of Patent Document 1, in order to perform the correlation analysis or the principal component analysis, it is necessary to compute the correlation matrix and execute the analysis processing after the compressed data columns are reorganized and converted to their original formats. For this reason, in the method of Patent Document 1, it is assumed that the number of indices “m” is sufficiently smaller than the number of samples “n.”

In a case where the m×m correlation matrix is too large to be stored in the memory as the number of indices “m” increases, it is difficult to perform a data analysis such as the correlation analysis or the principal component analysis disadvantageously. In an analysis of a social infrastructure system or the like, it is assumed that the number of explanatory indices reaches “1,000,000” in some cases. Therefore, it is necessary to optimize the analysis processing to keep up with an increase of the number of indices by simplifying data or processes while maintaining accuracy necessary in the analysis processing.

### Solutions to Problems

In view of the aforementioned problems, the present invention provides a method of optimizing the processing while maintaining accuracy necessary in the analysis processing by compressing the data amount to reduce the processing amount in the analysis processing of the correlation matrix consisting of a large amount of indices.

According to a representative aspect of the invention disclosed in this application, there is provided a computer provided with a processor, and a memory and a storage unit connected to the processor to create graph data provided with a vertex corresponding to a single index, an edge that links a pair of the vertices having a correlation, and an edge weight as a value of an element, from the correlation matrix data containing correlation values between a plurality of the indices as elements, the computer comprising a graph processing unit configured to acquire the correlation matrix data from the storage unit, detects elements of a spanning tree formed by linking vertices corresponding to the indices contained in the acquired correlation matrix data and an element having a value equal to or greater than a predetermined threshold value, and create the graph data from the detected elements.

According to another aspect of the invention, there is provided a computer provided with a processor and a memory connected to the processor and configured to execute a processing using correlation matrix data having correlation values between a plurality of indices as elements, the computer including: a graph processing unit configured to create first graph data having a list structure provided with a vertex corresponding to a single index, an edge that links a pair of the vertices having a correlation, and an edge weight as a value of the element from the correlation matrix data acquired from a storage unit, the graph processing unit having a control factor calculation section configured to calculate a maximum number of edges that can be contained in the first graph data in order to complete the processing using the correlation matrix data within a predetermined time, a spanning tree creating section configured to convert the correlation matrix data into second graph data having a list structure and create third graph data as a spanning tree provided with all vertices and a part of the edges of the second graph data, and a graph data creating section configured to create the first graph data on the basis of the second and third graph data using the maximum number of edges.

### Effects of the Invention

According to the present invention, it is possible to convert correlation matrix data consisting of a large amount of indices into compressed graph data that does not generate an accuracy failure depending on a constraint. As a result, it is possible to reduce the data amount and perform a fast graph processing such as a correlation analysis or a principal component analysis while maintaining necessary accuracy.

Other objects, configurations, and effects will become apparent by reading the following detailed description of embodiments.

### BRIEF DESCRIPTION OF THE DRAWINGS

FIG. 1 is a block diagram illustrating an exemplary configuration of a graph processing device according to a first embodiment of the present invention.

FIG. 2 is a block diagram illustrating an exemplary system configuration obtained by applying the graph processing device according to the first embodiment of the present invention.

FIG. 3 is an explanatory diagram illustrating exemplary work data according to the first embodiment of the present invention.

FIG. 4 is an explanatory diagram illustrating exemplary correlation matrix data according to the first embodiment of the present invention.

FIG. 5 is a flowchart illustrating an overview of the processing executed by the graph processing device according to the first embodiment of the present invention.

FIG. 6 is a flowchart illustrating an exemplary edge information amount calculation process according to the first embodiment of the present invention.

FIG. 7A is an explanatory diagram illustrating an exemplary frequency distribution table of correlation values according to the first embodiment of the present invention.

FIG. 7B is an explanatory diagram illustrating an exemplary edge information amount according to the first embodiment of the present invention.

FIG. 8 is a flowchart illustrating an exemplary control factor calculation process according to the first embodiment of the present invention.

FIG. 9 is an explanatory diagram illustrating an exemplary estimated processing time function f(E) according to the first embodiment of the present invention.

FIG. 10 is an explanatory diagram illustrating an exemplary estimation edge information amount used to determine a control factor according to the first embodiment of the present invention.

FIG. 11 is a flowchart illustrating an exemplary graph data creation process according to the first embodiment of the present invention.

FIG. 12A is an explanatory diagram illustrating an exemplary vertex list used in the graph data creation process according to the first embodiment of the present invention.

FIG. 12B is an explanatory diagram illustrating an exemplary edge list used in the graph data creation process according to the first embodiment of the present invention.

FIG. 13 is an explanatory diagram illustrating a concept of a round-off operation of the correlation value using the control factor in the graph data creation process according to the first embodiment of the present invention.

FIG. 14A is an explanatory diagram illustrating a vertex list and an edge list after executing the graph data creation process according to the first embodiment of the present invention.

FIG. 14B is an explanatory diagram illustrating a vertex list and an edge list after executing the graph data creation process according to the first embodiment of the present invention.

FIG. 15 is an explanatory diagram illustrating an exemplary graph displayed on the basis of the graph data according to the first embodiment of the present invention.

FIG. 16 is a block diagram illustrating an exemplary configuration of a graph processing device according to a second embodiment of the present invention.

FIG. 17 is a flowchart illustrating an exemplary control factor calculation process according to the second embodiment of the present invention.

FIG. 18A is an explanatory diagram illustrating an exemplary estimated memory consumption function g(E, B) according to the second embodiment of the present invention.

FIG. 18B is an explanatory diagram illustrating an exemplary estimated memory consumption function g(E, B) according to the second embodiment of the present invention.

FIG. 19 illustrates an exemplary round-off operation for the expressed bit number of the correlation value according to the second embodiment of the present invention.

FIG. 20 is a block diagram illustrating an exemplary configuration of a graph processing device according to a third embodiment of the present invention.

FIG. 21 is an explanatory diagram illustrating exemplary correlation matrix data according to the third embodiment of the present invention.

FIG. 22 is a flowchart illustrating an overview of the processing executed by the graph processing device according to the third embodiment of the present invention.

FIG. 23 is a flowchart illustrating an exemplary spanning tree creation process according to the third embodiment of the present invention.

FIG. 24 is an explanatory diagram illustrating a concept of the spanning tree creation process according to the third embodiment of the present invention.

FIG. 25A is an explanatory diagram illustrating a vertex list and an edge list after executing the spanning tree creation process according to the third embodiment of the present invention.

FIG. 25B is an explanatory diagram illustrating a vertex list and an edge list after executing the spanning tree creation process according to the third embodiment of the present invention.

FIG. 26 is an explanatory diagram illustrating an edge candidate list in the spanning tree creation process of the processing device according to the third embodiment of the present invention.

FIG. 27 is a flowchart illustrating an exemplary spanning tree creating step of the spanning tree creation process according to the third embodiment of the present invention.

FIG. 28 is an explanatory diagram illustrating a concept of the graph data creation process according to the third embodiment of the present invention.

FIG. 29A is an explanatory diagram illustrating a vertex list and an edge list after executing the graph data creation process according to the third embodiment of the present invention.

FIG. 29B is an explanatory diagram illustrating a vertex list and an edge list after executing the graph data creation process according to the third embodiment of the present invention.

FIG. 30 is an explanatory diagram illustrating an exemplary graph displayed on the basis of the graph data according to the third embodiment of the present invention.

FIG. 31 is an explanatory diagram illustrating an exemplary graph data creation process according to the third embodiment of the present invention.

### MODE FOR CARRYING OUT THE INVENTION

Embodiments of the present invention will now be described with reference to the accompanying drawings. In the attached drawings, like reference numerals denote like elements. Although the attached drawings illustrate specific embodiments according to a principle of the present invention, these are for understanding of the present invention and are not construed to limit the interpretation of the present invention.

First, an overview of the present invention will be described.

By executing an analysis processing such as a correlation analysis for work data, correlation matrix data representing a correlation between indices (such as a feature amount or an index) are created from the work data. Assuming that the number of indices is set to “m,” the correlation matrix data becomes matrix data having “m” rows and “m” columns. The correlation matrix data are data consisting of combinations of indices for identifying elements of the matrix and values of the elements.

Since the number of indices is large in the big data analysis, the size of the correlation matrix data is also large. For this reason, it is difficult to store the correlation matrix data in a memory. Therefore, it is necessary to frequently access a storage device or the like in order to acquire the correlation matrix data when the work data analysis processing is executed. As a result, a processing delay occurs due to a frequent access to the storage device.

The correlation matrix data having “m” rows and “m” columns has (m×m) elements, and it is necessary to process data on all elements in the analysis processing. Even in the case of “0” which indicates that there is no relationship between the indices, it is necessary to store the value “0.” For this reason, as the number of indices increases, the processing cost and the data amount increase.

(1) Conversion to Graph Data

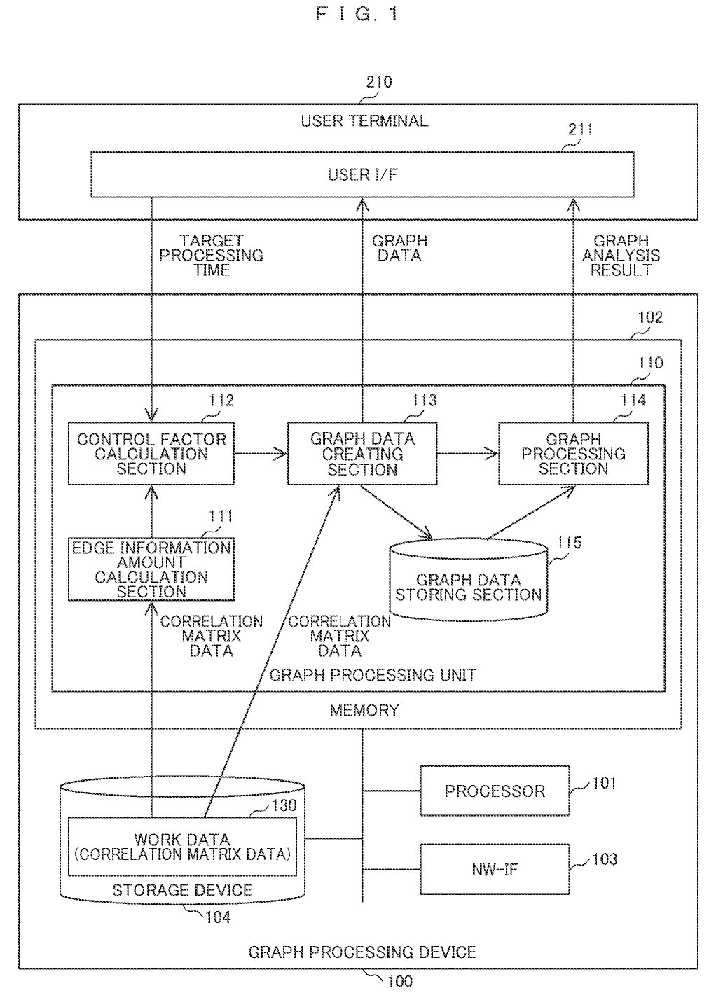

In order to address the aforementioned problems, a graph processing device 100 according to the present invention (refer to FIG. 1) converts the correlation matrix data into graph data. Here, the graph data is data having a data structure consisting of vertices representing indices, edges that connect a pair of correlated vertices, and weights of the edges representing the values of the elements, so that a connection relationship between the vertices can be recognized on the basis of the graph. The edge weight represents an intensity of the correlation between a pair of indices connected by the edge.

Since there is no edge between vertices having no correlation, it is not necessary to store data representing that there is no correlation in the case of the graph data. In addition, it is not necessary to store a vertex that is not connected to any vertex as the data. In contrast, in the case of the correlation matrix data, even when there is no correlation between a pair of indices, it is necessary to hold the data as an element having a value “0.” For this reason, the graph data has a data amount smaller than that of the correlation matrix data.

Therefore, it is possible to reduce the data amount by converting the correlation matrix data into the graph data. According to the present invention, the graph processing device 100 is characterized in that the correlation matrix data is not simply converted into graph data, but is converted into compressed graph data by which an accuracy failure is not easily generated, if possible, on the basis of a constraint.

Specifically, the present invention is characterized in that the following three processes are included.

(2) Adjustment of Number of Edges Contained in Graph Data

It may be difficult to sufficiently reduce the data amount even by directly converting the correlation matrix data into graph data. For this reason, the graph processing device 100 (refer to FIG. 1) according to the present invention adjusts the number of edges contained in the graph data depending on a target processing time which is a processing completion time of the analysis processing.

Specifically, the graph processing device 100 determines a threshold value for rounding off the correlation value on the basis of the target processing time. In addition, in the graph processing device 100, a value of an element is set to “0” if the value of the element is equal to or smaller than a threshold value. Then, the value of the element is converted into graph data. As described above, the value “0” represents that there is no correlation between a pair of indices. In this case, the edge also does not exist. For this reason, it is possible to reduce the number of edges contained in the graph data.

(3) Rounding-Off of Expressed Bit Number for Edge Weight

The graph processing device 100 according to the present invention rounds off the expressed bit number for the edge weight depending on a memory capacity. As a result, the graph data are further compressed to match the data size that can be stored in the memory.

(4) Creation of Graph Data Having Spanning Tree Structure

It may be difficult to maintain accuracy of the graph processing if it is difficult to constrain the target processing time just by reducing the number of edges using the threshold value. That is, in a case where the number of elements set to “0” using the threshold value is large, the structure of the converted graph data becomes sparse, so that it may be difficult to maintain a connected graph by disjointing the graph. The connected graph refers to a graph having an edge between two arbitrary vertices on the graph. In addition, the connected part graph refers to a connection component. If the connection component is disjointed to a plurality of components in a graph processing for traversing between neighboring nodes, it is impossible to transfer information between connection components and obtain a suitable result. For this reason, the graph processing device 100 according to the present invention creates graph data having a spanning tree structure of the graph in order to allow overall useful nodes to hold connection to another node in at least one side. The spanning tree is a tree structure consisting of overall nodes of the graph and a part of the edges and guarantees connectivity of the graph data.

Specifically, the graph processing device 100 creates a spanning tree on the basis of the correlation matrix data. In addition, the graph processing device 100 creates graph data so as to store element data of the created spanning tree structure while removing values of elements equal to or smaller than a threshold value. It is possible to prevent disjointing of the graph that may generate an accuracy failure by holding the element data of the spanning tree structure.

By executing the aforementioned processing, it is possible to reduce the data amount necessary in the processing. That is, since all of the graph data can be stored in the memory, it is possible to provide a fast processing and suppress a processing cost by reducing the data amount. Furthermore, in order to prevent disjointing of the graph, the spanning tree structure is held in the created graph data. Therefore, it is possible to optimize the graph processing while maintaining necessary accuracy.

### First Embodiment

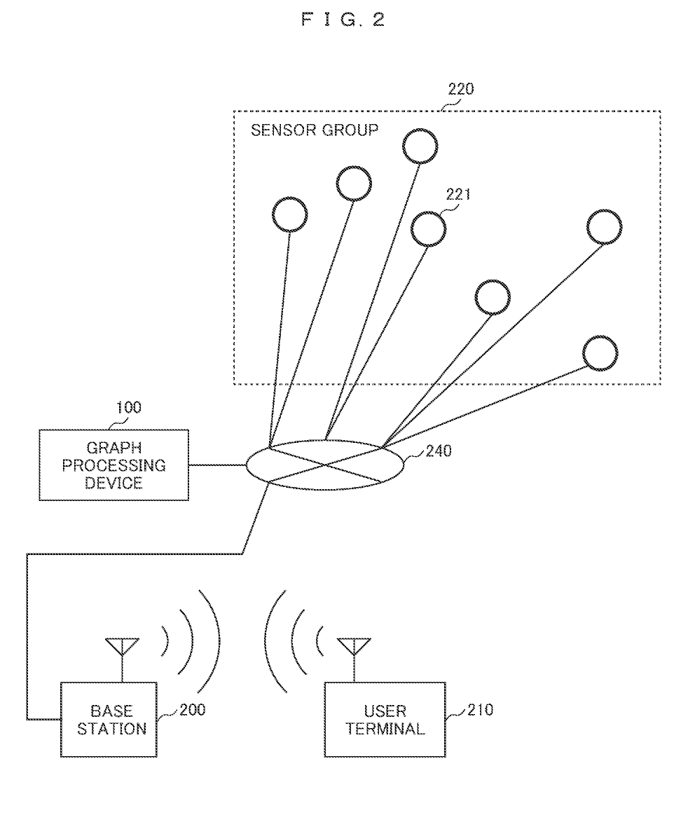

FIG. 1 is a block diagram illustrating an exemplary configuration of the graph processing device 100 according to the first embodiment of the present invention. FIG. 2 is a block diagram illustrating an exemplary system configuration to which the graph processing device 100 according to the first embodiment of the present invention is applied.

The system of FIG. 2 includes a graph processing device 100, a base station 200, a user terminal 210, and a sensor group 220.

A plurality of sensors 221 included in the graph processing device 100, the base station 200, and the sensor group 220 are connected to each other through a network 240. The network 240 may include, for example, a wide area network (WAN), a local area network (LAN), and the like. However, the present invention is not limited by the type of the network 240.

The user terminal 210 is connected to the graph processing device 100 and the like through the base station 200 via a radio communication. Note that the user terminal 210 and the base station 200 may be connected to each other in a wired manner, or the user terminal 210 may be directly connected to the network 240.

The graph processing device 100 acquires work data 130 from each sensor of the sensor group 220 and stores the acquired work data 130 in the storage device 104. In addition, the graph processing device 100 executes the graph processing in response to an instruction of the user terminal 210.

The user terminal 210 includes, for example, a personal computer, a tablet terminal, and the like. The user terminal 210 has a processor (not illustrated), a memory (not illustrated), a network interface (not illustrated), and an input/output device (not illustrated). The input/output device includes a display, a keyboard, a mouse, a touch panel, and the like.

The user terminal 210 provides a user interface 211 for operating the graph processing device 100. The user interface 211 inputs a target processing time to the graph processing device 100 and receives the graph data output from the graph processing device 100, a result of the graph processing, and the like.

The graph processing device 100 includes a processor 101, a memory 102, a network interface 103, and a storage device 104 as hardware components.

The processor 101 executes a program stored in the memory 102. As the processor 101 executes the program, various functional parts of the graph processing device 100 can be implemented. In the following description, in a case where the processing is described by focusing on the functional parts, this means that a program that implements the functional parts is executed by the processor 101.

The memory 102 stores a program executed by the processor 101 and information used in execution of the program. The memory 102 may include a dynamic random-access memory (DRAM). The program and the information stored in the memory 102 will be described below. The network interface 103 is an interface for connection to external devices through the network such as a WAN or a LAN.

The storage device 104 stores various types of information. The storage device 104 may include a hard disk drive (HDD), a solid-state device (SSD), and the like. According to this embodiment, the work data 130 are stored in the storage device 104. Note that the correlation matrix data representing correlations of various data in the work data 130 may be stored in the storage device 104.

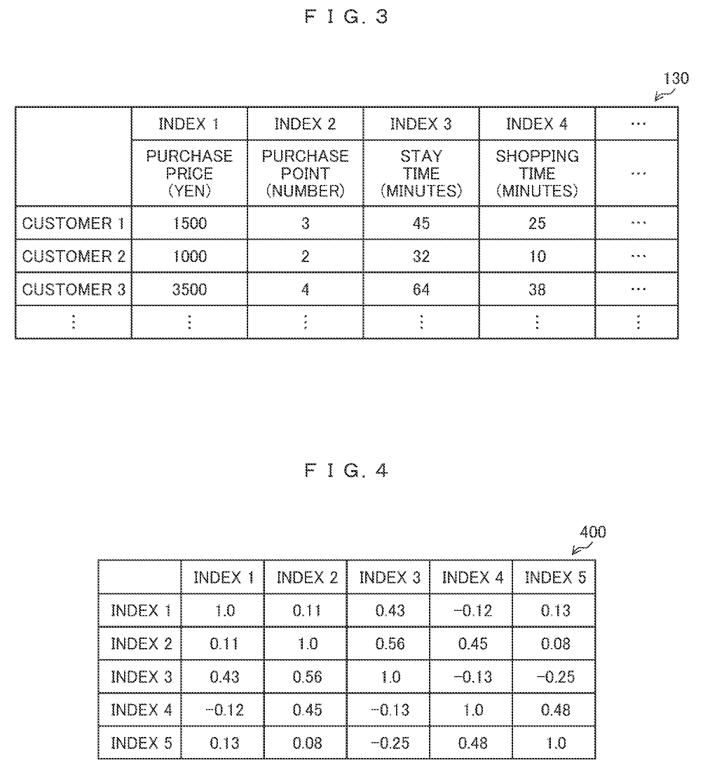

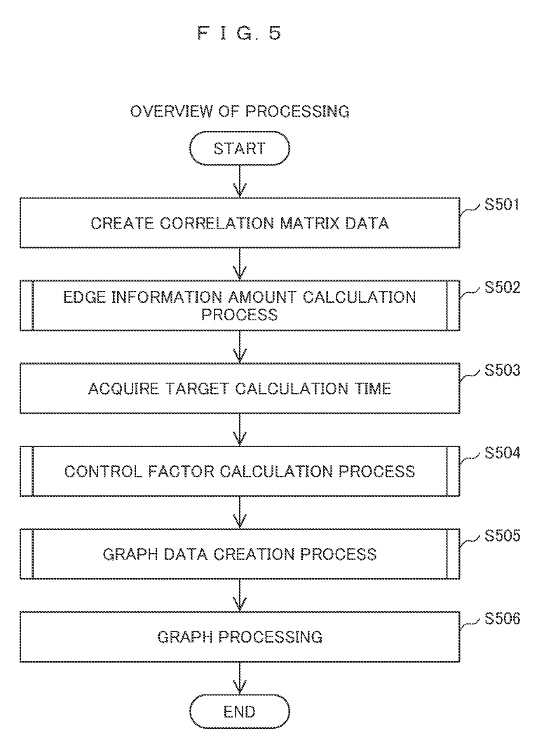

Here, examples of the work data 130 and the correlation matrix data 400 will be described with reference FIGS. 3 and 4. FIG. 3 is an explanatory diagram illustrating an example of the work data 130 according to the first embodiment of the present invention. FIG. 4 is an explanatory diagram illustrating an example of the correlation matrix data 400 according to the first embodiment of the present invention.

FIG. 3 illustrates work data 130 of a retail store. The work data 130 describes information on each customer, such as a purchase price, a purchase point, a stay time, and a shopping time. The “PURCHASE PRICE,” the “PURCHASE POINT,” the “STAY TIME,” and the “SHOPPING TIME” are called indices.

The correlation matrix data 400 are matrix data containing correlations between indices as elements. For example, the matrix data according to this embodiment contains information representing a correlation between index 1 “PURCHASE PRICE” and index 2 “PURCHASE POINT” as an element. Here, the correlation between INDEX 1 and INDEX 2 is given as a correlation value. For example, the correlation value is computed using the following Formula (1).

$$\begin{matrix}[ Formula 1 ] & \\ \frac{S 12}{S 1 \times S 2} & ( 1 )\end{matrix}$$

where “S1” denotes a standard deviation of INDEX 1, “S2” denotes a standard deviation of INDEX 2, and “S12” denotes a covariance between INDICES 1 and 2. The correlation value is set to “−1” or greater and “1” or smaller. As the correlation value approaches “1,” this means a strong “positive correlation.” As the correlation value approaches “−1,” this means a strong “negative correlation.” In addition, if the correlation value approaches “0,” this means there is no correlation between indices.

That is, the correlation matrix data 400 has a matrix type data structure having correlation values for overall combinations of the indices as elements and represent a relationship between indices. In the following description, the correlation matrix data 400 computed from the work data 130 is stored in the storage device 104 in advance.

Next, returning to FIG. 1, the program and the information stored in the memory 102 will be described.

The memory 102 stores a program for implementing the graph processing unit 110. The graph processing unit 110 converts the correlation matrix data 400 into graph data, that is, creates the graph data from the correlation matrix data 400. In addition, the graph processing unit 110 executes an arbitrary graph processing using the graph data. The graph processing unit 110 includes a plurality of program modules. Specifically, the graph processing unit 110 includes an edge information amount calculation section 111, a control factor calculation section 112, a graph data creating section 113, a graph processing section 114, and a graph data storing section 115.

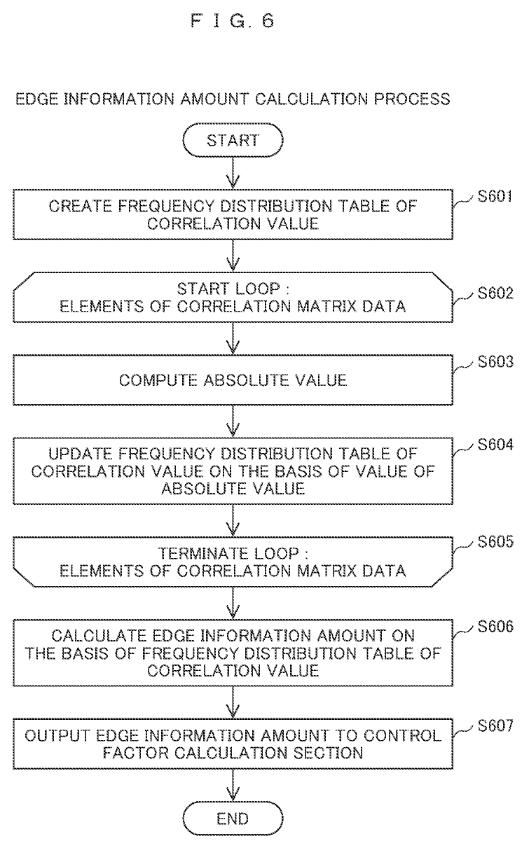

The edge information amount calculation section 111 reads elements of the correlation matrix data 400 from the storage device 104 and calculates the edge information amount representing a relationship between the correlation value and the number of edges. In addition, the edge information amount calculation section 111 outputs the calculated edge information amount to the control factor calculation section 112. Here, the edge information amount is information for estimating the number of edges that can be included when the correlation matrix data 400 is converted into the graph data. The processing executed by the edge information amount calculation section 111 will be described below in more details with reference to FIG. 6.

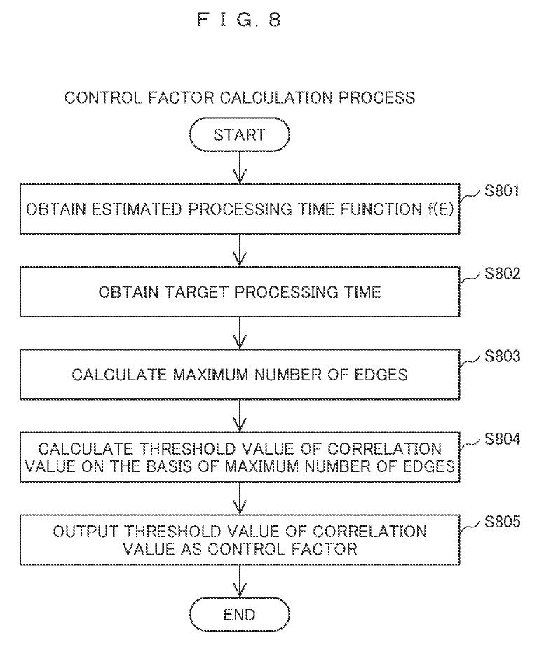

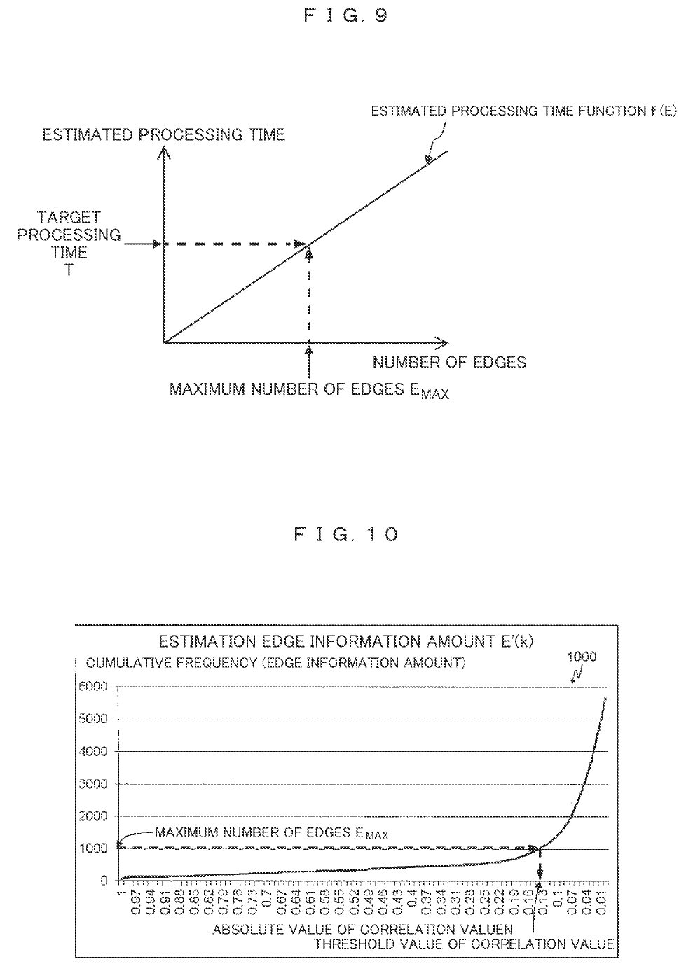

The control factor calculation section 112 calculates a control factor used in compression of data in order to convert the correlation matrix data 400 into the graph data. According to this embodiment, the control factor calculation section 11 calculates a threshold value for adjusting the number of edges included in the graph data as a control factor on the basis of the edge information amount and the target processing time. In addition, the control factor calculation section 112 outputs the calculated control factor to the graph data creating section 113. The processing executed by the control factor calculation section 112 will be described below in more details with reference to FIG. 8.

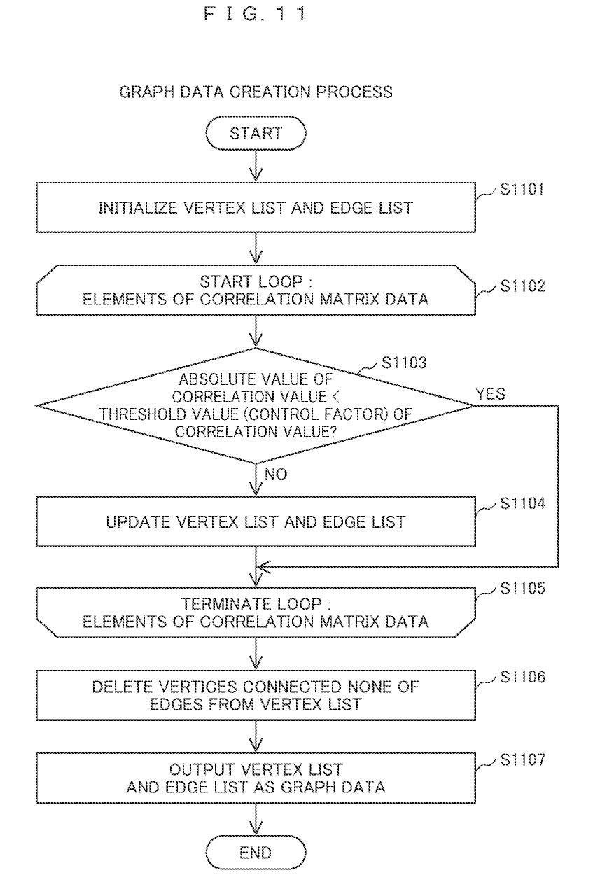

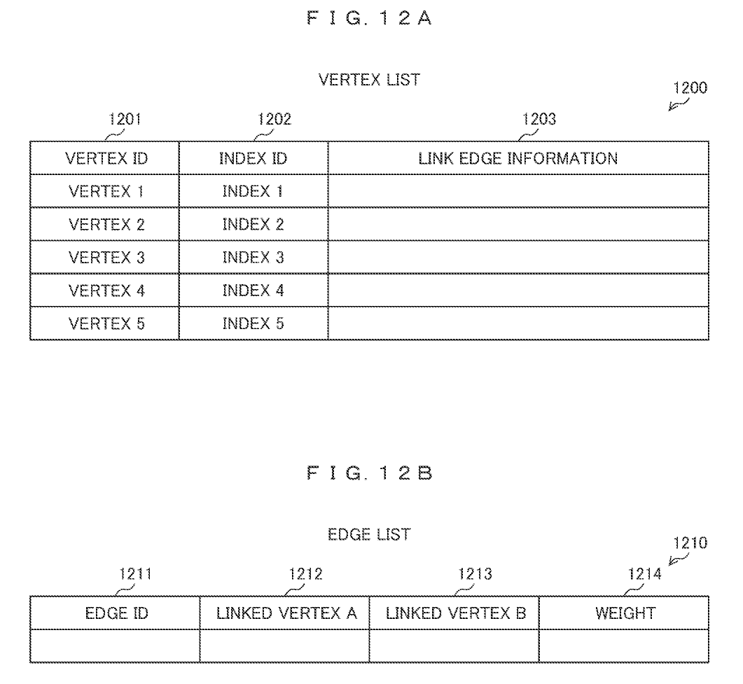

The graph data creating section 113 creates the graph data from the correlation matrix data 400 using the calculated control factor. The graph data creating section 113 stores the created graph data in the graph data storing section 115 and transmits the created graph data to the user terminal 210. The processing executed by the graph data creating section 113 will be described below in more details with reference to FIG. 11.

The graph processing section 114 executes an arbitrary graph processing using the graph data. The graph processing may include, for example, a Page Rank processing, a centricity computation processing, or the like that can be employed to compute an eigenvalue of the matrix operation. The present invention is not limited to details of the graph processing, but may be applied to various graph algorithms used for general purposes. The graph processing section 114 transmits a result of the graph processing to the user terminal 210.

Next, a processing executed by the graph processing device 100 according to this embodiment will be described. FIG. 5 is a flowchart illustrating an overview of the processing executed by the graph processing device 100 according to the first embodiment of the present invention.

The graph processing device 100 executes the following processes periodically or when a process start instruction is received from the user terminal 210.

The graph processing device 100 creates the correlation matrix data 400 from the work data 130 stored in the storage device 104 (step S501). Specifically, the graph processing unit 110 creates the correlation matrix data 400. Note that the processing of step S501 may be omitted in a case where the correlation matrix data 400 are stored in the storage device 104.

The graph processing device 100 executes the edge information amount calculation process (step S502). Specifically, the edge information amount calculation section 111 analyzes correlation matrix data 400 and calculates the edge information amount on the basis of a result of the analysis. The edge information amount calculation process executed by the edge information amount calculation section 111 will be described below in more details with reference to FIG. 6.

The graph processing device 100 acquires the target processing time from the user terminal 210 (step S503). Specifically, the graph processing unit 110 requests the user terminal 210 to input the target processing time. In this case, as the user interface 211 receives the request, an operation screen for entering the target processing time is displayed on a display unit or the like, so that the target processing time entered on the operation screen is transmitted to the graph processing device 100. The graph processing device 100 inputs the target processing time received from the user terminal 210 to the control factor calculation section 112.

The graph processing device 100 executes the control factor calculation process using the edge information amount and the target processing time (step S504). Specifically, the control factor calculation section 112 calculates the control factor used to create the compressed graph data using the edge information amount and the target processing time. The control factor calculation process executed by the control factor calculation section 112 will be described below in more details with reference to FIG. 8.

The graph processing device 100 executes the graph data creation process using the control factor (step S505). Specifically, the graph data creating section 113 creates the graph data from the correlation matrix data 400 using the calculated control factor. The graph data creation process executed by the graph data creating section 113 will be described below in more details with reference to FIG. 11.

The graph processing device 100 executes the graph processing using the created graph data (step S506). Specifically, the graph processing section 114 executes a predetermined graph processing using the created graph data and transmits a result of the graph processing to the user terminal 210.

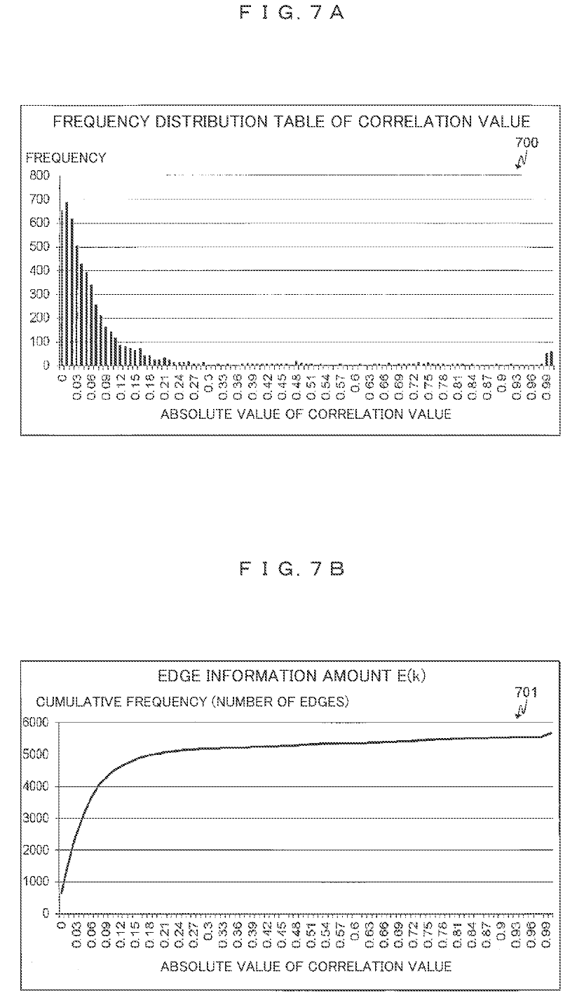

FIG. 6 is a flowchart illustrating an exemplary edge information amount calculation process according to the first embodiment of the present invention. FIG. 7A is an explanatory diagram illustrating an exemplary correlation value frequency distribution table 700 according to the first embodiment of the present invention. FIG. 7B is an explanatory diagram illustrating an exemplary edge information amount according to the first embodiment of the present invention.

The edge information amount calculation section 111 creates a correlation value frequency distribution table (histogram) 700 of the correlation matrix data 400 (step S601)

Here, the correlation value frequency distribution table 700 is a histogram illustrating a frequency distribution of occurrences of values counted for each predetermined range of the correlation value and becomes a graph illustrated in FIG. 7A. In FIG. 7A, the value range is set to “0.01.” Note that it is assumed that the value range of the correlation value frequency distribution table 700 is set in advance. However, the value range may be changed depending on an external input.

The edge information amount calculation section 111 starts a loop processing for the elements of the correlation matrix data 400 (step S602). First, the edge information amount calculation section 111 selects one of the elements from the correlation matrix data 400 and reads a value of the selected element (correlation value).

The edge information amount calculation section 111 calculates an absolute value of the value of the read element, that is, an absolute value of the correlation value (step S603). The edge information amount calculation section 111 updates the correlation value frequency distribution table 700 on the basis of the absolute value of the calculated correlation value (step S604). Specifically, the edge information amount calculation section 111 increments the count within the value range including the absolute value of the correlation value. Note that the edge information amount calculation section 111 updates the correlation value frequency distribution table 700 and then deletes the values of the read elements.

The edge information amount calculation section 111 determines whether or not the processing has been completed for overall elements of the correlation matrix data 400 (step S605). If it is determined that the processing has not been completed for overall elements of the correlation matrix data 400, the edge information amount calculation section 111 returns to step S602 and executes the same processing. Meanwhile, if it is determined that the processing has been completed for overall elements of the correlation matrix data 400, the edge information amount calculation section 111 advances to step S606.

If the loop processing for the elements of the correlation matrix data 400 is completed, the correlation value frequency distribution table 700 has a state illustrated in FIG. 7A.

The edge information amount calculation section 111 calculates the edge information amount on the basis of the correlation value frequency distribution table 700 (step S606) and outputs the calculated edge information amount to the control factor calculation section 112 (step S607). Then, the edge information amount calculation section 111 terminates the process. Specifically, the following processing is executed.

The edge information amount calculation section 111 calculates a total sum of the count number until the absolute value “k” of the correlation value, that is, cumulative frequency of the count number. The result is plotted by setting the abscissa as an absolute value of the correlation value and setting the ordinate as the cumulative frequency of the count number calculated as the cumulative frequency. The edge information amount calculation section 111 calculates a function E(k) representing a relationship between the absolute value of the correlation value and the cumulative frequency as the edge information amount from the plot result. According to this embodiment, the edge information amount E(k) is given as the plot 701 illustrated in FIG. 7B.

The cumulative frequency represents a total sum of the count number until the absolute value of the correlation value of the correlation value frequency distribution table 700 becomes “k.” For example, “E(0.3)” refers to a total sum of the count number within a range of the absolute value of the correlation value from “0” to “0.3.” Therefore, “E(1)” is equal to the number of all elements of the correlation matrix data 400.

FIG. 8 is a flowchart illustrating an exemplary control factor calculation process according to the first embodiment of the present invention. FIG. 9 is an explanatory diagram illustrating an exemplary estimated processing time function f(E) according to the first embodiment of the present invention. FIG. 10 is an explanatory diagram illustrating an example of the estimation edge information amount used to determine the control factor according to the first embodiment of the present invention.

The control factor calculation section 112 starts the processing as the edge information amount is input. The control factor calculation section 112 obtains the estimated processing time function f(E) by setting the edge information amount E(k) as a variable (step S801).

The control factor calculation section 112 may calculate the estimated processing time function f(E) on the basis of the graph analysis processing algorithm. For example, in a case where an eigenvalue problem used in the principal component analysis is solved in the graph analysis processing, the function can be given as the following Formula (2), assuming that “a” denotes a repetition time of the convergent computation of the algorithm, “b” denotes a processing time per unit edge, and “E” denotes a variable.

[Formula 2]

f(E)=a×b×E (2)

FIG. 9 illustrates the estimated processing time function f(E) obtained from Formula (2). Note that the edge information amount E(k) is given as a domain of the estimated processing time function f(E).

Next, the control factor calculation section 112 acquires the target processing time from the user terminal 210 (step S802). For example, the control factor calculation section 112 requests the user terminal 210 to enter the target processing time. As this request is received through the user interface 211, the user terminal 210 displays an operation screen or the like for entering the target processing time on a display unit. In the following description, it is assumed that “T” denotes the acquired target processing time.

The control factor calculation section 112 calculates the maximum number of edges E_{MAX} that can be completed through the graph processing within the target processing time on the basis of the target processing time and the estimated processing time function f(E) (step S803).

According to this embodiment, the control factor calculation section 112 may calculate the maximum number of edges E from Formula (2). Specifically, the maximum number of edges E_{MAX} is calculated as expressed in the following Formula (3). The dotted line of FIG. 9 indicates the maximum number of edges E_{MAX} calculated using Formula (3).

$$\begin{matrix}[ Formula 3 ] & \\ {E}_{MAX} = \frac{T}{a \times b} & ( 3 )\end{matrix}$$

The control factor calculation section 112 calculates the threshold value of the correlation value on the basis of the edge information amount E(k) and the maximum number of edges E_{MAX} (step S804). Specifically, the following processing is executed.

First, the control factor calculation section 112 obtains the estimation edge information amount E′ (k) using the edge information amount E(k). According to this embodiment, as expressed in the following Formula (4), the estimation edge information amount E′ (k) is obtained. The estimation edge information amount E′ (k) is given as a plot 1000 illustrated in FIG. 10.

[Formula 4]

E′(k)=E(1)−E(k) (4)

The control factor calculation section 112 calculates the threshold value of the correlation value on the basis of the estimation edge information amount E′(k) and the maximum number of edges E_{MAX}. Specifically, the control factor calculation section 112 calculates the absolute value k of the correlation value by setting the left side of Formula (4) as the maximum number of edges E_{MAX} and modifying it as expressed in the following Formula (5). The calculated absolute value k of the correlation value is the threshold value of the correlation value. The dotted line of FIG. 10 indicates the threshold value of the correlation value calculated using Formula (5). The threshold value of the correlation value is used as a threshold value (control factor) for rounding off the correlation value in the graph data creation process as described below.

[Formula 5]

E(k)=E(1)−E_{MAX} (5)

The control factor calculation section 112 outputs the calculated threshold value of the correlation value as the control factor to the graph data creating section 113 (step S805), and terminates the process.

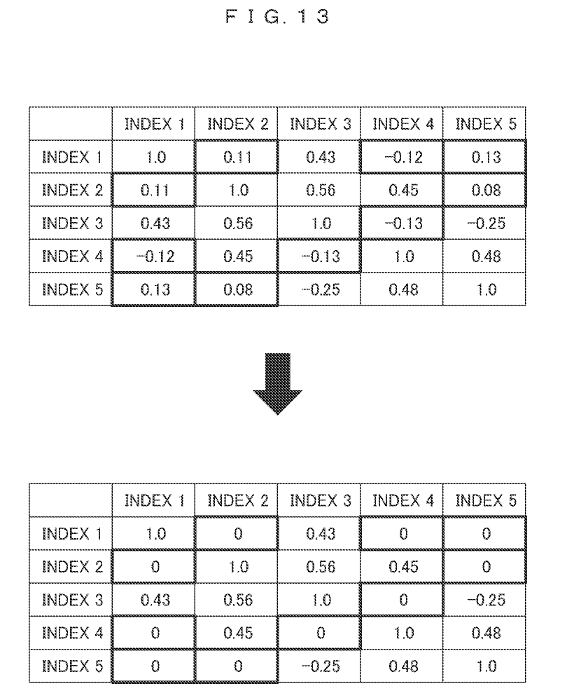

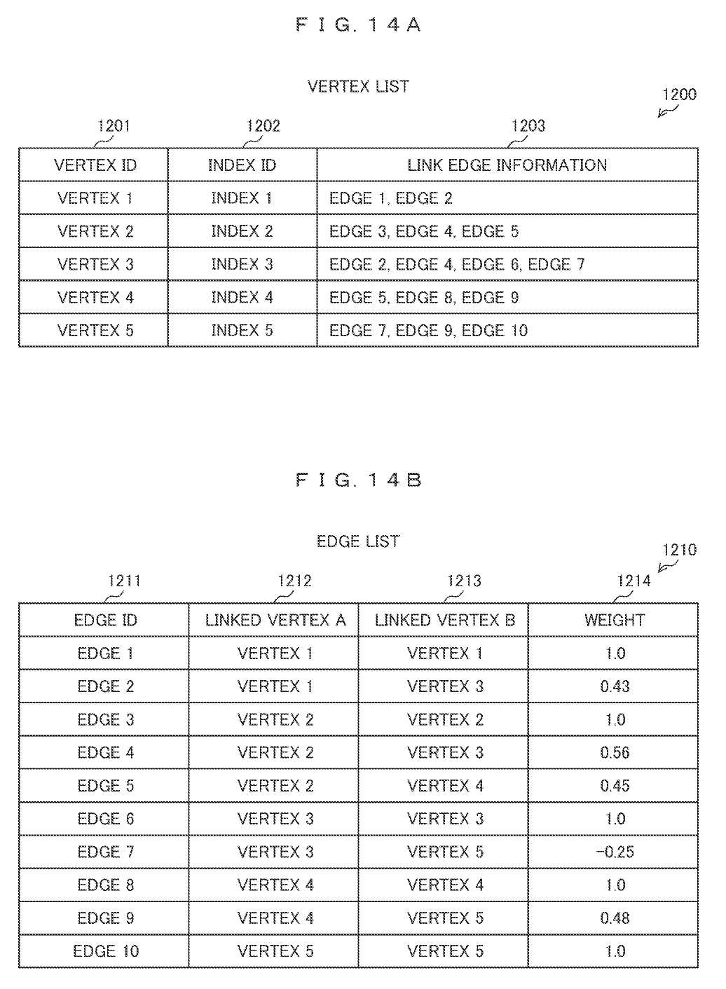

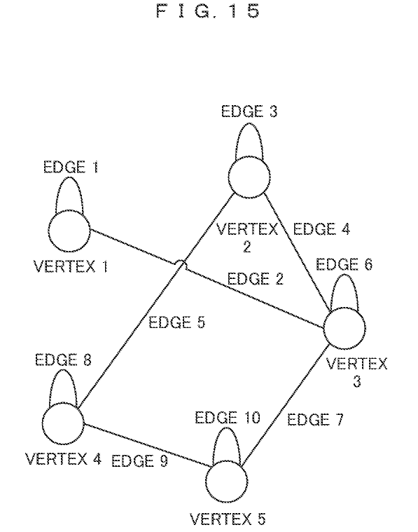

FIG. 11 is a flowchart illustrating an exemplary graph data creation process according to the first embodiment of the present invention. FIG. 12A is an explanatory diagram illustrating an exemplary vertex list 1200 used in the graph data creation process according to the first embodiment of the present invention. FIG. 12B is an explanatory diagram illustrating an exemplary edge list 1210 used in the graph data creation process according to the first embodiment of the present invention. FIG. 13 is an explanatory diagram illustrating a concept of rounding-off of the correlation value using the control factor in the graph data creation process according to the first embodiment of the present invention. FIGS. 14A and 14B are explanatory diagrams illustrating the vertex list 1200 and the edge list 1210 after executing the graph data creation process according to the first embodiment of the present invention. FIG. 15 is an explanatory diagram illustrating an exemplary graph displayed on the basis of the graph data according to the first embodiment of the present invention.

First, the vertex list 1200 and the edge list 1210 will be described.

The vertex list 1200 is information for managing the information on the vertices (indices) and edges that link the vertices (indices) in the graph data. The vertex list 1200 of FIG. 12A contains vertex id 1201, index id 1202, and link edge information 1203.

The vertex ID 1201 stores identification information for uniquely identifying a vertex. A single vertex ID is given to a single vertex. The index ID 1202 is identification information on the index corresponding to the vertex. In the graph data, a single index is managed as a single vertex. The link edge information 1203 is information on edges connected to the vertex corresponding to the vertex ID 1201.

The edge list 1201 is information for managing the edges (sides) in the graph data. The edge list 1210 of FIG. 12B contains edge ID 1211, linked vertex A 1212, linked vertex B 1213, and weight 1214.

The edge ID 1211 stores identification information for uniquely identifying an edge. A single edge ID is given to a single edge. The linked vertex A 1212 and the linked vertex B 1213 store identification information on a pair of vertices linked by the edge. The weight 1214 stores an edge weight, that is, a correlation value.

The graph data creating section 113 starts the process as the control factor is input. First, the graph data creating section 113 initialize the vertex list 1200 and the edge list 1210 (step S1101).

Specifically, the graph data creating section 113 creates entries in the vertex list 1200 as many as the number of all indices of the correlation matrix data 400. The identification information of the indices is set in the index ID columns 1202 of the created entries. The graph data creating section 113 allocates vertex IDs to each index and sets the vertex IDs allocated to the vertex IDs 1201 of each entry. At this timing, the link edge information 1203 has a void state. In addition, the graph data creating section 113 creates a void edge list 1210.

The graph data creating section 113 starts a loop processing for the elements of the correlation matrix data 400 (step S1102). First, the graph data creating section 113 reads one of the elements from the correlation matrix data 400. If the elements of the graph data creating section 113 are read one by one, the input/output (I/O) operation is generated frequently. Therefore, the correlation matrix data 400 may be read on a row basis, and the read elements are temporarily held in the memory 102.

The graph data creating section 113 determines whether or not the absolute value of the correlation value of the read element is smaller than the threshold value (control factor) of the correlation value (step S1103). If it is determined that the absolute value of the correlation value of the read element is smaller than the threshold value (control factor) of the correlation value, the graph data creating section 113 advances to step S1105.

If it is determined that the absolute value of the correlation value of the read element is equal to or greater than the threshold value (control factor) of the correlation value, the graph data creating section 113 updates the vertex list 1200 and the edge list 1210 (step S1104). Specifically, the following process is executed.

The graph data creating section 113 adds an entry in the edge list 1210 and sets identification information on the edge in the EDGE ID 1211 of the added entry. In addition, the graph data creating section 113 sets two indices corresponding to the read element in the linked vertex A 1212 and the linked vertex B 1213 of the added entry. In addition, the graph data creating section 113 sets the correlation value of the read element in the weight 1214 of the added entry.

The graph data creating section 113 searches for an entry having an index ID 1202 matching with the identification information of the index set in the linked vertex A 1212 by referring to the vertex list 1200. The graph data creating section 113 sets the identification information of the edge set in the edge ID 1211 in the link edge information 1203 of the added entry. Similarly, the graph data creating section 113 searches for an entry having an index ID 1202 matching with the identification information of the index set in the linked vertex B 1213 and sets the identification information of the edge in the link edge information 1203 of this entry.

Note that, in a case where the same identification information of the edge as the identification information of the edge to be added is stored in the link edge information 1203, the graph data creating section 113 does not set the identification information of the edge to be added because it is not necessary.

Hereinbefore, the process of step S1104 has been described.

The graph data creating section 113 determines whether or not the processing has been completed for overall elements of the correlation matrix data 400 (step S1105). If it is determined that the processing has not been completed for overall elements of the correlation matrix data 400, the graph data creating section 113 returns to step S1102, and the same processing is executed. Otherwise, if it is determined that the processing has been completed for overall elements of the correlation matrix data 400, the graph data creating section 113 advances to step S1106.

The loop processing for the elements of the correlation matrix data 400 corresponds to a process of setting a value of the element having an absolute value of the correlation value smaller than the threshold value (control factor) of the correlation value to zero “0” and then creating the graph data as illustrated in FIG. 13.

The graph data creating section 113 deletes an entry of the vertex that is not connected to any edge from the vertex list 1200 by referring to the vertex list 1200 (step S1106). Specifically, the graph data creating section 113 searches for an entry of the edge whose identification information is not stored in link edge information 1203 and deletes this entry from the vertex list 1200.

If the aforementioned process is completed, the vertex list 1200 and the edge list 1210 have states illustrated in FIGS. 124A and 14B.

The graph data creating section 113 outputs the vertex list 1200 and the edge list 1210 as the graph data (step S1107) and terminates the process. According to this embodiment, the graph data creating section 113 outputs the vertex list 1200 and the edge list 1210 to the graph data storing section 115 and transmits the vertex list 1200 and the edge list 1210 to the user terminal 210. The user terminal 210 may display the graph of FIG. 15 on the basis of the received graph data.

According to this embodiment, the graph data includes the vertex list 1200 and the edge list 1210. However, the present invention is not limited to the list expression, and any other graph expression methods may also be employed.

Here, the data amounts of the correlation matrix data 400 and the graph data will be described with reference to FIGS. 4, 14A, 14B, and 15.

As illustrated in FIG. 4, in the case of the correlation matrix data 400 having five rows and five columns, it is necessary to hold correlation values for each of twenty five combinations of indices. Meanwhile, in the case of the graph data, it is sufficient to hold information on five vertices and information on ten edges including edge weights. Therefore, the graph processing device 100 can compress the data amount by converting the correlation matrix data 400 into the graph data.

According to the first embodiment, the graph processing device 100 does not simply convert only the correlation matrix data 400 into the graph data, but adjusts the number of edges included in the graph data using the control factor and then creates the graph data in order to complete the processing within the target processing time. As a result, since the created graph data are further compressed, the data can be arranged in the memory 102, so that a fast graph analysis processing can be performed using the graph data in the memory 102. That is, by compressing the correlation matrix data into the graph data, it is possible to reduce the data amount in a big data analysis such as a correlation analysis or a principal component analysis for a large amount of indices and implement a fast processing.

### Modifications

In the first embodiment, the amount of data held as the edges is reduced by setting a value of the element having an absolute value of the correlation value smaller than the threshold value of the correlation value to “0.” However, the present invention is not limited thereto. For example, the graph data creating section 113 may extract only an element having an absolute value of the correlation value greater than the threshold value of the correlation value and create the graph data from the extracted element.

### Second Embodiment

Next, a second embodiment will be described. According to the second embodiment, a memory constraint amount selected by a user is considered in addition to the target processing time, and further, compressed graph data are created. Specifically, the control factor calculation section 112 calculates a threshold value and an expressed bit number of the edge weight as the control factor in order to adjust the number of edges included in the graph data. As a result, the graph processing device 100 compresses the data amount by reducing the number of edges and rounding off the expressed bit number of the edge weight. A second embodiment will now be described by focusing on differences from the first embodiment. Note that like reference numerals denote like elements as in the first embodiment, and they will not be described repeatedly.

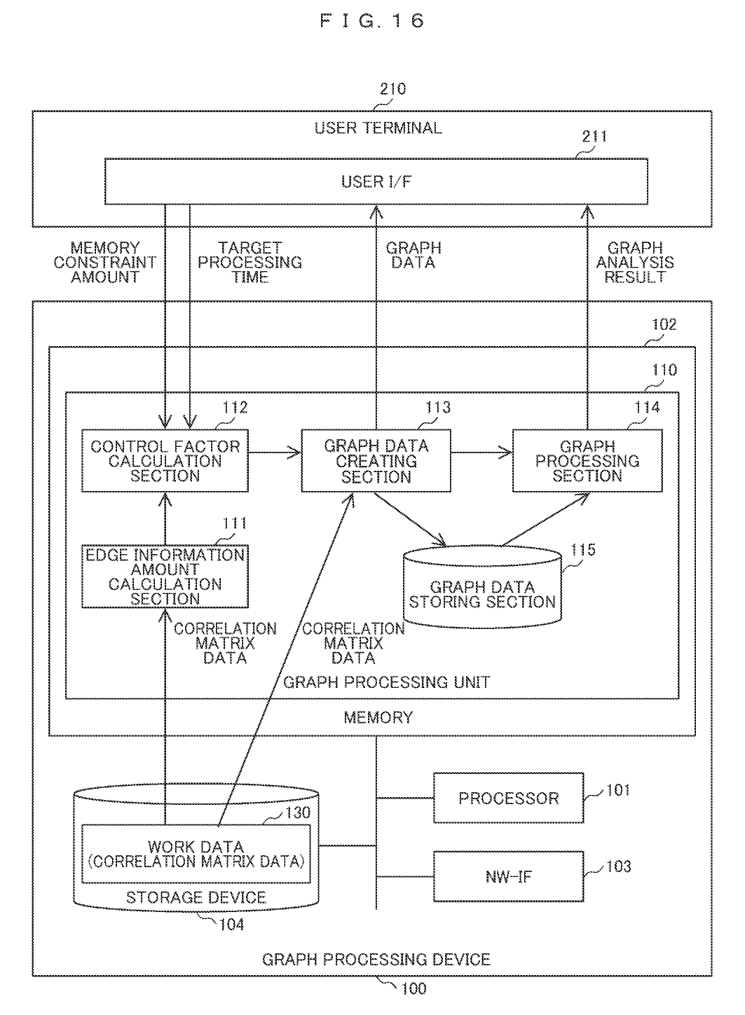

FIG. 16 is a block diagram illustrating an exemplary configuration of the graph processing device 100 according to the second embodiment of the present invention. Note that a system configuration of the graph processing device 100 is similar to that of the first embodiment, and its components will not be described repeatedly.

The second embodiment is different from the first embodiment in that the user terminal 210 inputs a memory constraint amount in addition to the target processing time as illustrated in FIG. 16. The control factor calculation section 112 calculates a threshold value of the correlation value and a round-off bit number for the edge weight on the basis of the target processing time and the memory constraint amount. Other configurations are similar to those of the first embodiment.

A data type of the correlation matrix data 400 is similar to that of the first embodiment, and it will not be described repeatedly. An overview of the processing executed by the graph processing device 100 is also similar to that of the first embodiment, and it will not be described repeatedly. In addition, the edge information amount calculation process is similar to that of the first embodiment, and it will not be described repeatedly. According to the second embodiment, a part of the control factor calculation process and a part of the graph data creation process are different.

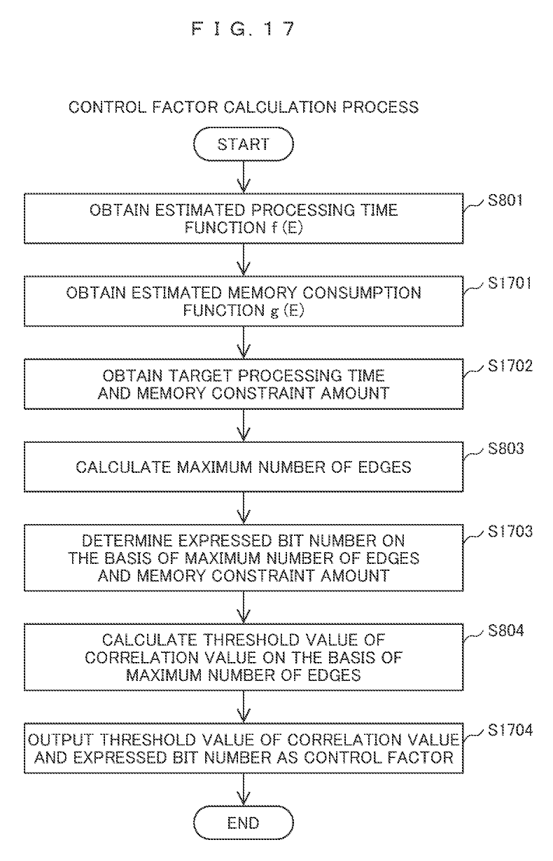

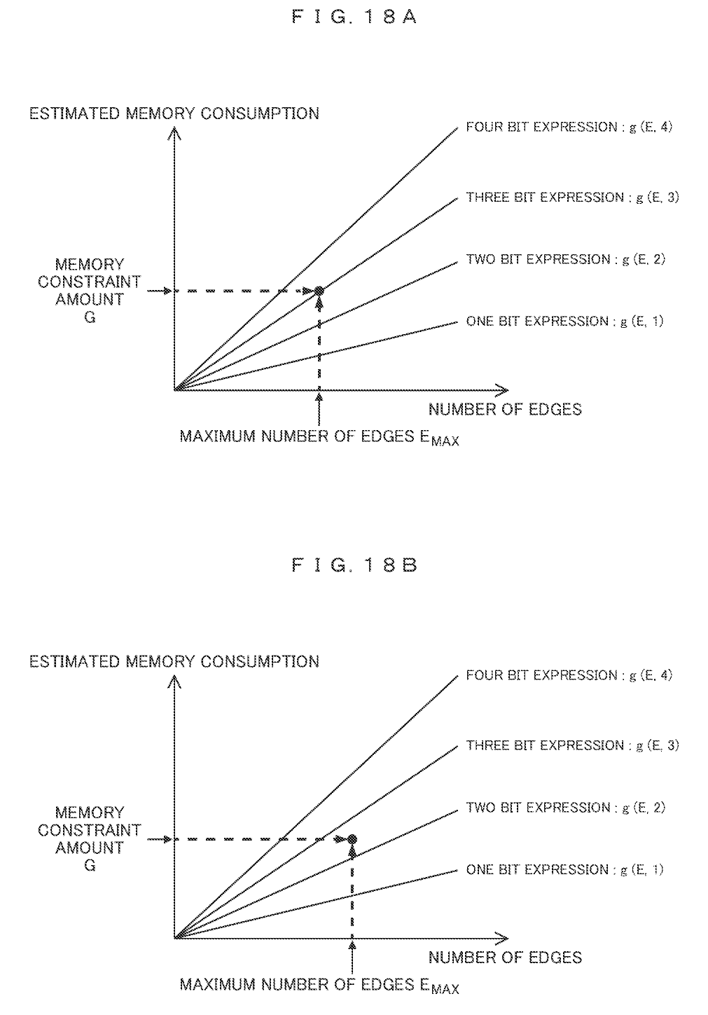

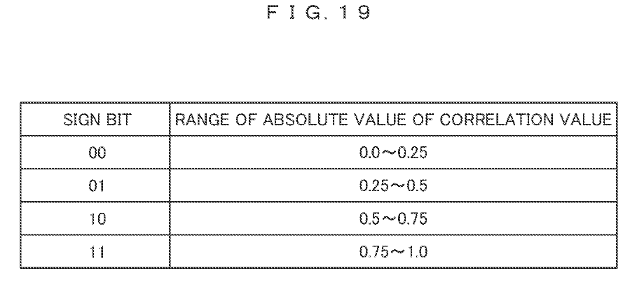

FIG. 17 is a flowchart illustrating an exemplary control factor calculation process according to the second embodiment of the present invention. FIGS. 18A and 18B are explanatory diagrams illustrating an exemplary estimated memory consumption function g(E, B) according to the second embodiment of the present invention. FIG. 19 is an explanatory diagram illustrating an exemplary rounding-off operation for the expressed bit number of the correlation value according to the second embodiment of the present invention.

In the control factor calculation process according to the second embodiment, the control factor calculation section 112 obtains the estimated processing time function f(E) and then obtains the estimated memory consumption function g(E, B) regarding edge information amount for each expressed bit number of the correlation value (step S1701). Here, “E” denotes the number of edges, and “B” denotes the expressed bit number.

A plurality of estimated memory consumption functions g(E, B) exit depending on how many bits the edge weight is expressed. For example, assuming that the weight is expressed by one bit, “x” denotes a memory consumption per edge, “E” denotes the number of edges, and “y” denotes the bit number of the edge, the estimated memory consumption function g(E, B) is expressed as the following Formula (6).

[Formula 6]

g(E,y)=x×y×E (6)

FIGS. 18A and 18B illustrate the estimated memory consumption function g(E, B) obtained from Formula (6). Note that the edge information amount E(k) is given as a domain of the estimated memory consumption function g(E, B).

After step S1701, the control factor calculation section 112 acquires the target processing time and the memory constraint amount from the user terminal 210 (step S1702). The memory constraint amount may be acquired using the same method as that of the target processing time. In the following description, it is assumed that “T” denotes the acquired target processing time, and “G” denotes the memory constraint amount.

The control factor calculation section 112 calculates the maximum number of edges E_{MAX} (step S803) and determines the expressed bit number of the edge weight on the basis of the maximum number of edges E_{MAX}, the memory constraint amount, and the estimated memory consumption function g(E, B) (step S1703). Specifically, the following processing is executed.

The control factor calculation section 112 calculates an estimated memory consumption by applying the maximum number of edges E_{MAX} to each estimated memory consumption function g(E, B). The control factor calculation section 112 detects whether or not the calculated estimated memory consumption satisfies the following Formula (7).

[Formula 7]

g(E_{MAX},B)≦G (7)

The control factor calculation section 112 selects the greatest bit number of the estimated memory consumption that satisfies Formula (7) and determines the selected bit number as the expressed bit number of the edge weight.

For example, in the example of FIG. 18A, the expressed bit number of the edge weight is determined as “3 bits.” In the example of FIG. 18B, the expressed bit number of the edge weight is determined as “2 bits.”

The control factor calculation section 112 calculates the threshold value of the correlation value (step S804) and then outputs the threshold value of the correlation value and the expressed bit number to the graph data creating section 113 as the control factor (step S1704). Then, the process is terminated.

The flow of the graph creation process according to the second embodiment is similar to the graph creation process of the first embodiment (refer to FIG. 11). However, a part of the processing of step S1104 is different.

Specifically, in a case where the correlation value is set in weight 1214 of the entry added to the edge list 1210, the graph data creating section 113 rounds off the correlation value on the basis of the expressed bit number input as the control factor, so that the rounded correlation value is set in weight 1214.

For example, in a case where the expressed bit number of the correlation value before the round-off operation is “4 bits,” and the bit number is rounded off to “3 bits,” the uppermost bit is designated as a sign bit. For example, a bit “0” may correspond to a positive correlation value, and a bit “1” may correspond to a “negative” correlation value. In addition, the sign bits may be allocated as illustrated in FIG. 19 depending on a magnitude of the absolute value of the correlation value. Note that the sign may be designated using methods other than that of FIG. 19.

Other processes are similar to those of the first embodiment.

According to the second embodiment, the graph data can be further compressed by rounding off the expressed bit number of the edge weight depending on the memory constraint amount. That is, it is possible to create the graph data of a data amount that can be processed within the target processing time under a constraint of an available memory capacity in the system. As a result, a fast graph processing can be performed by arranging all the graph data created from the correlation matrix data 400 in the memory 10 and using the data arranged in the memory 102.

### Third Embodiment

Next, a third embodiment will be described. According to the third embodiment, graph data are created by holding element data having a spanning tree structure in which all of the nodes are connected with edges without a closed route in order to prevent an accuracy failure caused by disjointing of the graph as well as reduction of the edges caused by applying the threshold value (control factor) based on the target processing time. Specifically, a spanning tree is created from the correlation matrix data in advance, and values of the elements equal to or smaller than the threshold value are eliminated such that the created element data having the spanning tree structure are held on the spanning tree. That is, an element included in the tree structure is not removed, for example, even when it is equal to or smaller than the threshold value. Then, the graph data is created using this element. As a result, the graph processing device 100 can prevent disjointing of the graph that may cause an accuracy failure. The third embodiment will now be described by focusing on differences from the first embodiment. Note that like reference numerals denote like elements as in the first embodiment, and they will not be described repeatedly.

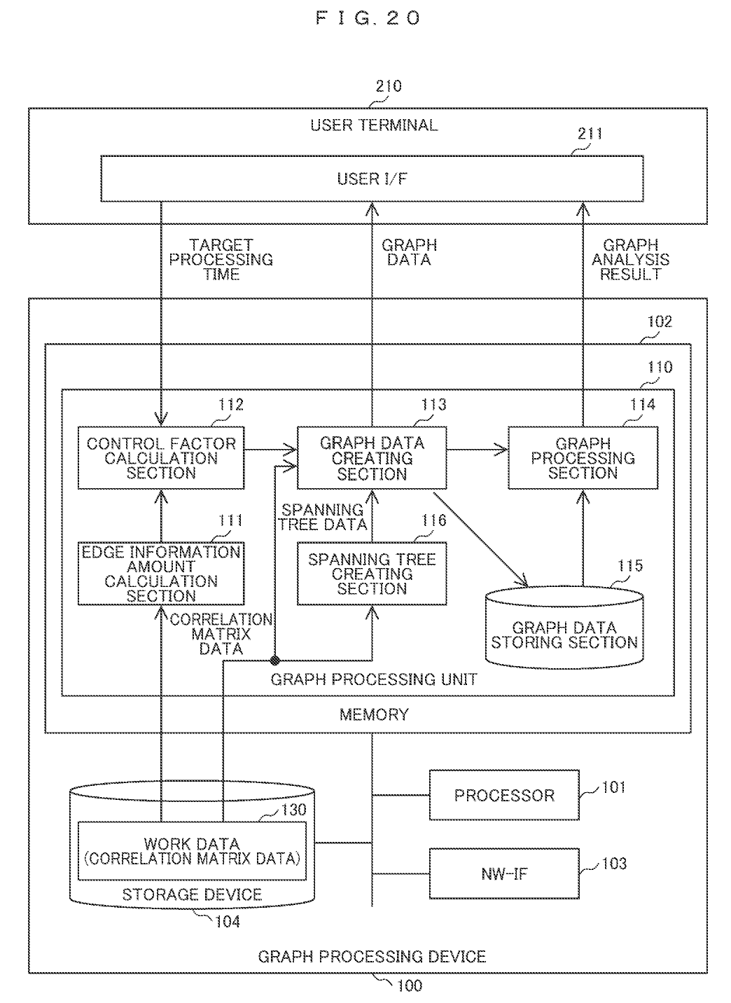

FIG. 20 is a block diagram illustrating an exemplary configuration of the graph processing device 100 according to the third embodiment of the present invention. Note that a system configuration of the graph processing device 100 is similar to that of the first embodiment, and it will not be described repeatedly.

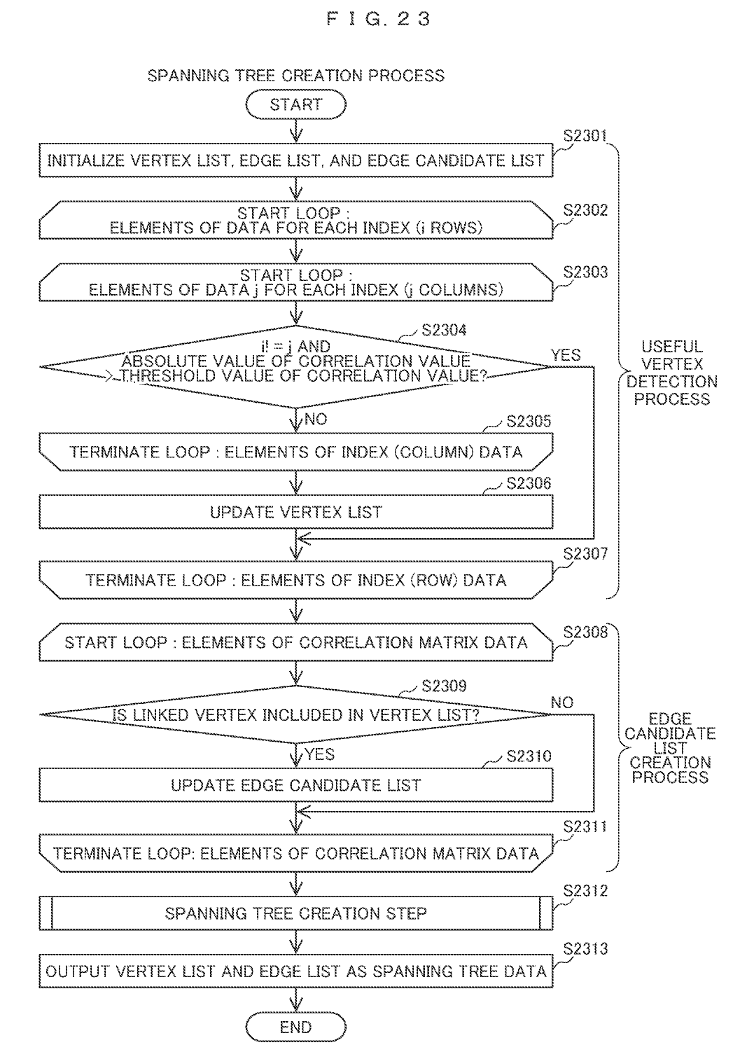

As illustrated in FIG. 20, the third embodiment is different from the first embodiment in that the graph processing unit 110 is provided in addition to the edge information amount calculation section 111, the control factor calculation section 112, the graph data creating section 113, and the graph processing section 114. The spanning tree creating section 116 creates the spanning tree data by receiving the correlation matrix data 400. A processing executed by the spanning tree creating section 116 will be described below in more details with reference to FIG. 23.

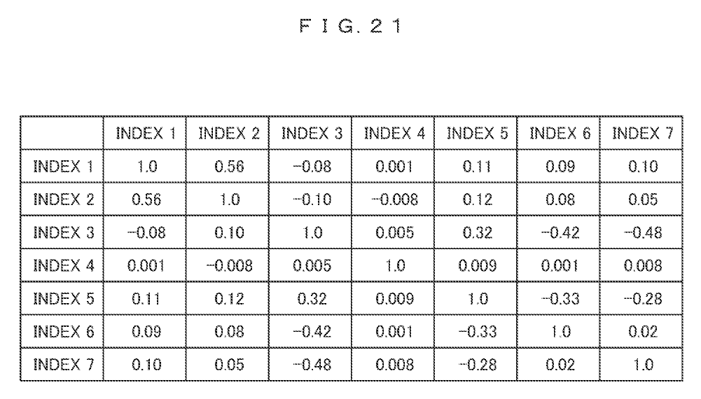

A data format of the correlation matrix data 400 is similar to that of the first embodiment, and it will not be described repeatedly. In addition, FIG. 21 illustrates exemplary correlation matrix data 400 for describing the third embodiment.

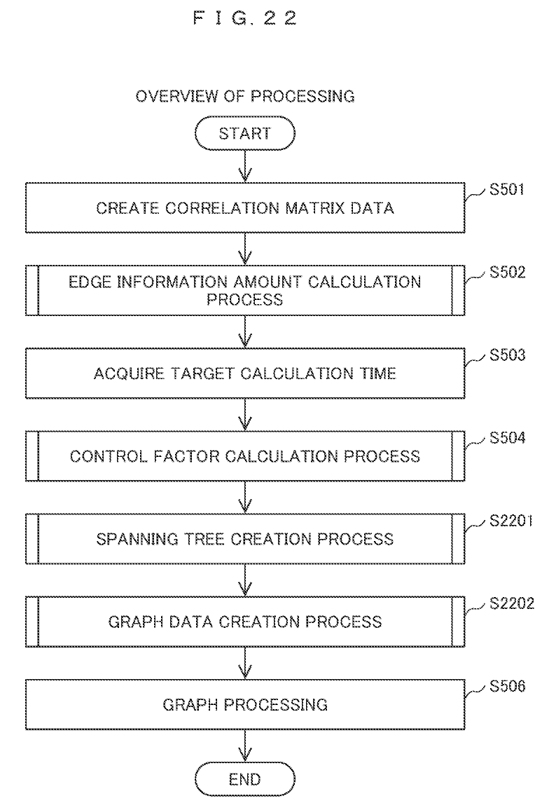

A processing executed by the graph processing device 100 according to this embodiment will be described. FIG. 22 is a flowchart illustrating an overview of the processing executed by the graph processing device 100. In the processing according to the third embodiment, a spanning tree creation process (step S2201) is executed between the correlation matrix data creation process (step S501) and the graph data creation process (step S2202). In FIG. 22, the spanning tree creation process (step S2201) is inserted immediately before the graph data creation process (step S2202). However, the spanning tree creation process may be inserted into any position as long as it is between the correlation matrix data creation process (step S501) and the graph data creation process (step S2202).

In the spanning tree creation process (step S2201), specifically, the spanning tree creation processing section 116 creates spanning tree data by receiving the correlation matrix data 400. The processing executed by the spanning tree creating section 116 according to the third embodiment will be described below in more details with reference to FIG. 23.

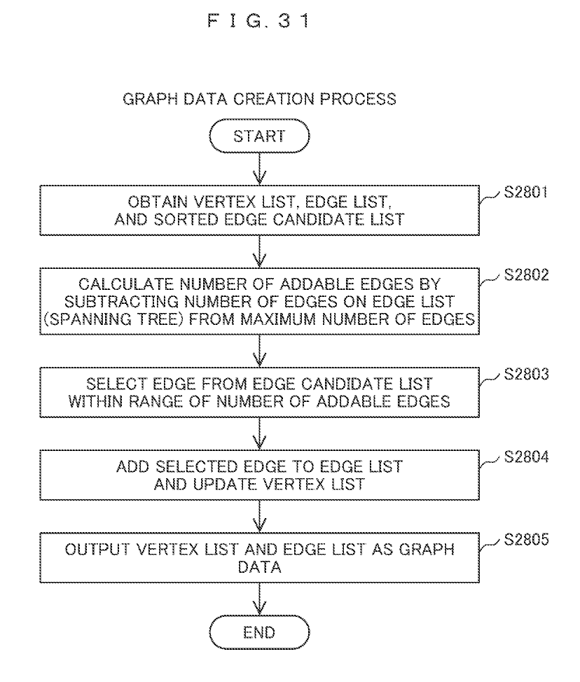

The edge information amount calculation process is similar to that of the first embodiment, and it will not be described repeatedly. The control factor calculation process is also similar to those of the first and second embodiments, and it will not be described repeatedly. According to the third embodiment, a part of the graph data creation process is different from those of the first and second embodiments. The graph data creation process according to the third embodiment will be described below in more details with reference to FIG. 31.

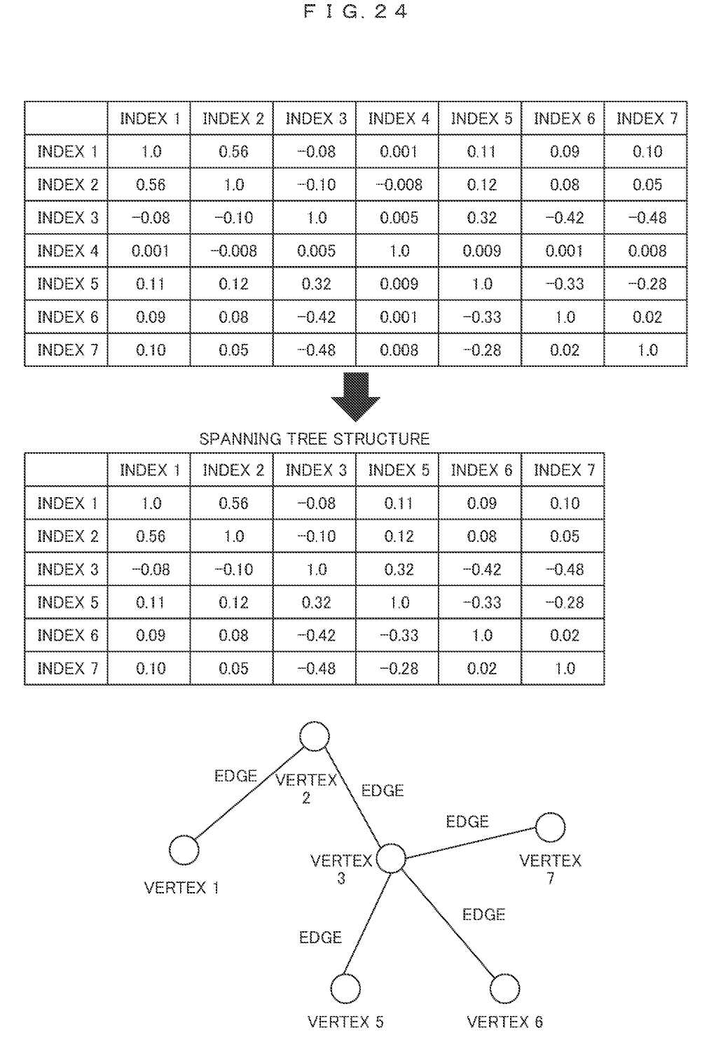

FIG. 23 is a flowchart illustrating an exemplary spanning tree creation process according to the third embodiment of the present invention. FIG. 24 is an explanatory diagram illustrating a concept of the spanning tree creation process according to the third embodiment of the present invention. FIG. 24 conceptually illustrates a series of processing flows for removing an index (noise) having a low correlation with all other indices from the correlation matrix data and creating a spanning tree by organizing remaining indices other than the noise as nodes.

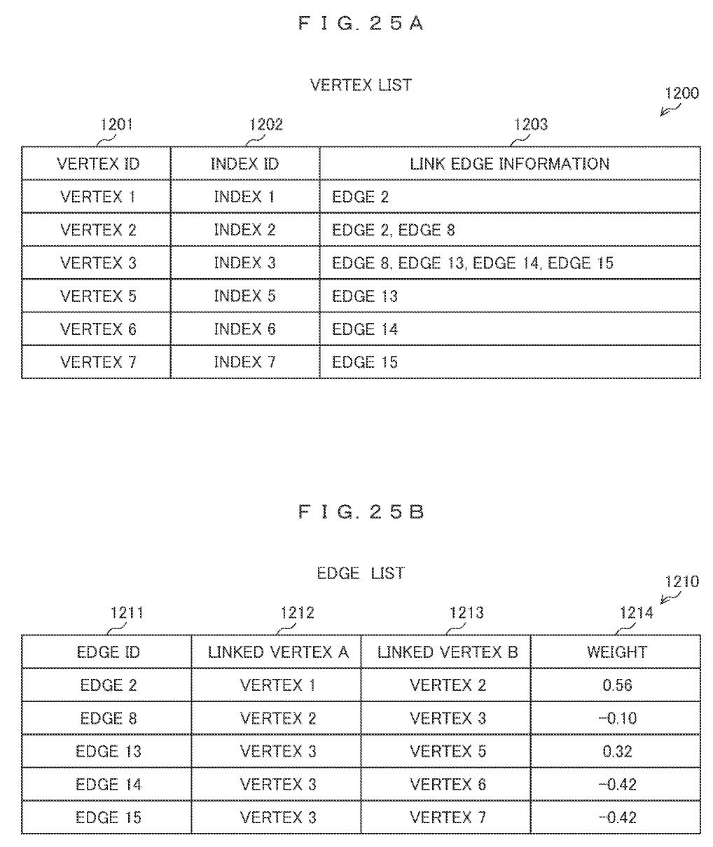

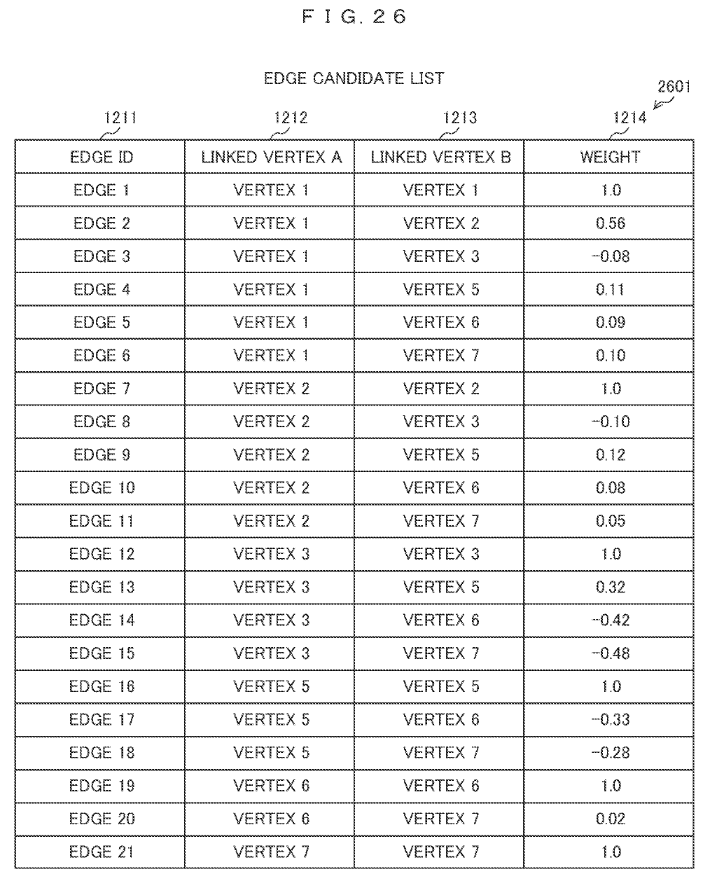

FIGS. 25A and 25B are explanatory diagrams illustrating examples of the vertex list 1200 and edge list 1210 after the spanning tree creation process according to the third embodiment of the present invention is executed. FIG. 26 is an explanatory diagram illustrating an exemplary edge candidate list 2601 used in the spanning tree creating process according to the third embodiment of the present invention.

The vertex list 1200 and the edge list 1210 are similar to those of the first embodiment, and they will not be described repeatedly. The edge candidate list 2601 is information for managing candidates for edges to be added to the edge list. Similar to the edge list 1210, the edge candidate list 2601 includes edge ID 1211, linked vertex A 1212, linked vertex B 1213, and weight 1214

The spanning tree creating section 116 initializes the vertex list 1200, the edge list 1210, and the edge candidate list 2601 (step S2301). Specifically, the spanning tree creating section 116 creates entries in the vertex list 1200 as many as the number of all indices of the correlation matrix data 400 and sets identification information of the indices in INDEX ID 1202 for the created entries. The spanning tree creating section 116 allocates a vertex ID to each index and sets the vertex ID given in the vertex ID 1201 of the entry. At this timing, the link edge information 1203 has a void state. In addition, the spanning tree creating section 116 creates a void edge list 1210 and a void edge candidate list 2601.

The spanning tree creating section 116 starts a useful vertex detection process (steps S2301 to S2307). In the useful vertex detection process (steps S2301 to S2307), an unnecessary index having a low correlation with all other indices is removed from the correlation matrix data. Specifically, it is determined whether or not all elements of each row of the correlation matrix data 400 have correlation values equal to or greater that a threshold value (step S2304). Here, the threshold value of the correlation value is different from the threshold value (control factor) calculated in step S804 of FIG. 8. By setting a value smaller than the control factor in advance, a sufficiently small value that can be determined as being unnecessary is removed. In the example of FIG. 21, the threshold value is set to “0.01.”

If it is determined that any one of other indices has an absolute value of the correlation value of the read element equal to or greater than the threshold value of the correlation value, steps S2305 and S2306 are skipped, and the process advances to step S2307.

If it is determined that overall elements of the corresponding row are equal to or smaller than the threshold value, the spanning tree creating section 116 updates the vertex list 1200 to exclude an unnecessary index (step S2306). Specifically, the spanning tree creating section 116 deletes the entry of the vertex ID corresponding to this index ID from the vertex list 1200. In the example of FIG. 21, since the threshold value is set to “0.01,” the entry of index 4 is deleted.

The spanning tree creating section 116 determines whether or not the process has been completed for elements of the rows of the correlation matrix data 400 (step S2307). If it is determined that the processing has not been completed for overall elements of the correlation matrix data 400, the spanning tree creating section 116 returns to step S2302 and executes the same processing. Otherwise, if it is determined that the processing has been completed for overall elements of the correlation matrix data 400, the spanning tree creating section 116 advances to step S2308.

The useful vertex detection process (steps S2301 to S2307) has been described hereinbefore. Note that this process may also be omitted.

Then, the spanning tree creating section 116 executes an edge candidate list creation process (steps S2308 to S2311). The edge candidate list 2601 is information for managing information on edges to be added to the edge list 1210 and serves as intermediate data.

The spanning tree creating section 116 starts a loop processing for elements of the correlation matrix data 400 (step S2308). First, the graph data creating section 113 reads one of the elements from the correlation matrix data 400. The spanning tree creating section 116 determines whether or not the vertex list 1200 contains a linked vertex (step S2309).

If it is determined that vertex list 1200 contains a linked vertex, the spanning tree creating section 116 updates the edge candidate list 2601 (step 2310). Specifically, the spanning tree creating section 116 adds an entry in the edge candidate list and sets the identification information of the edge in EDGE ID 1211 for the added entry. In addition, the spanning tree creating section 116 sets a pair of indices corresponding to the read element in linked vertex A 1212 and linked vertex B 1213 for the added entry. Furthermore, the spanning tree creating section 116 sets the correlation value of the read element in weight 1214 of the added entry.

If it is determined that there is no linked vertex in the vertex list 1200, the spanning tree creating section 116 advances to step S2311. The spanning tree creating section 116 determines whether or not the processing has been completed for overall elements of the correlation matrix data 400 (step S2311). If it is determined that the processing has not been completed for overall elements of the correlation matrix data 400, the spanning tree creating section 116 returns to step S2308 and executes the same processing. Otherwise, if it is determined that the processing has been completed for overall elements of the correlation matrix data 400, the spanning tree creating section 116 advances to step S2312.

The edge candidate list creation process (steps S2308 to S2311) has been described hereinbefore. If the aforementioned processing is completed, the edge candidate list has a state illustrated in FIG. 26.

The spanning tree creating section 116 executes a spanning tree creation process (S2312). Specifically, the spanning tree creating section 116 executes the spanning tree creation process (S2312) on the basis of the vertex list 1200 and the edge candidate list 2601 and updates the vertex list 1200 and the edge list 1210 used to construct the spanning tree.

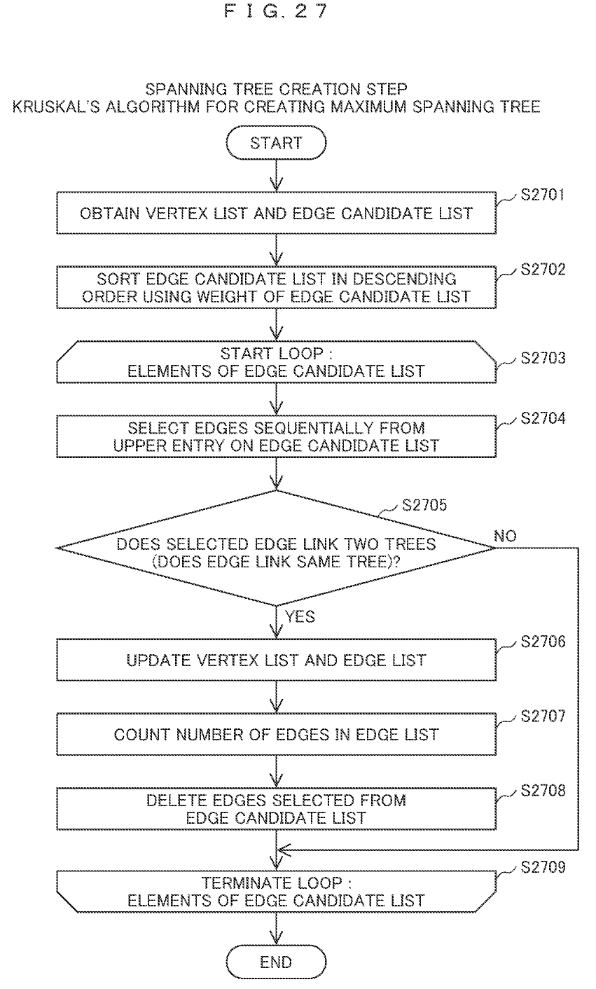

Here, any technique that enables creation of the spanning tree may be employed in the spanning tree creation process. For example, neighboring numbers may be simply linked to each other without a burden on the computation load. For example, a spanning tree creation algorithm such as the Kruskal's algorithm or the Prim's algorithm may also be employed. The most preferable structure to improve analysis accuracy is the maximum spanning tree technique. An exemplary method of obtaining the maximum spanning tree using the Kruskal's algorithm will be described below with reference to FIG. 27.

Note that a plurality of techniques may be prepared for the spanning tree creation process, and one of them may be selected in response to an input from the user terminal 210. If the aforementioned processing is completed, the vertex list 1200 and the edge list 1210 have states illustrated in FIGS. 25A and 25B.

The spanning tree creating section 116 outputs the vertex list 1200 and the edge list 1210 as the spanning tree data (step S2313) and terminates the processing. According to this embodiment, the spanning tree creating section 116 inputs the vertex list 1200 and the edge list 1210 to the graph data creating section 113.

FIG. 27 is a flowchart illustrating an exemplary processing of the spanning tree creation process according to the third embodiment of the present invention. FIG. 27 illustrates an exemplary method of obtaining the maximum spanning tree using the Kruskal's algorithm.

The spanning tree creating section 116 acquires the vertex list 1200 and the edge candidate list 2601 (step S2701)

The spanning tree creating section 116 sorts the edge candidate list 2601 in descending order (step S2703). Specifically, the values of the edge candidate list 1214 are rearranged in descending order using overall values of weight 1214 of the edge candidate list 2601.

The spanning tree creating section 116 starts a loop operation for the elements of the edge candidate list 2601 (step S2703). In addition, one of the edges is selected and read sequentially from the upper entry on the edge candidate list 2601 (step S2704).

The spanning tree creating section 116 determines whether or not the read edge links a pair of trees in the graph of the edge list 1210 (an undirected graph having no closed route in the link). That is, it is determined whether or the read edge links the same tree. If it is determined that the read edge is not an edge that associates a pair of trees with each other, the spanning tree creating section 116 advances to step S2707.

If it is determined that the read edge is an edge that links a pair of trees, the edge list 1210 is updated (step S2706). Specifically, the read edge is added to the edge list 1210 as a new entry. In addition, link edge information is set in the vertex list 1200.

If an edge is added to the edge list 1210, the spanning tree creating section 116 counts the number of edges included in the edge list by incrementing the counter (S2707). In addition, the added edge is deleted from the edge candidate list (S2708). If the processing of step S2708 is completed, the spanning tree creating section 116 returns to step S2704, and selects an edge of the next entry from the edge candidate list.

The spanning tree creating section 116 determines whether or not the processing has been completed for overall elements of the edge candidate list 2601 (step S2709). If it is determined that the processing has not be completed for overall elements of the edge candidate list, the spanning tree creating section 116 returns to step S2703, and executes the same processing. Otherwise, if it is determined that the processing has been completed for overall elements of the edge candidate list, the spanning tree creation process is terminated, and the process advances to step S2313 (refer to FIG. 23). Through the aforementioned processing, a list of edges of the spanning tree consisting of overall vertices included in the vertex list 1200 is stored in the edge list 1210.

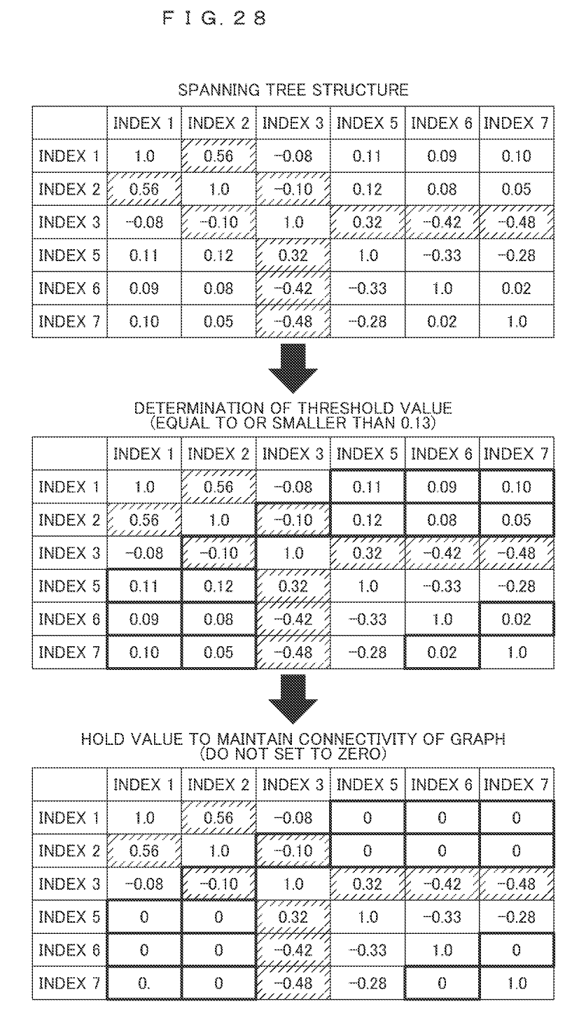

FIG. 28 is an explanatory diagram illustrating a concept of the graph data creation process according to the third embodiment of the present invention. In FIG. 28, the hatched range of the correlation matrix data indicates the spanning tree data, and the range surrounded by the bold lines indicates data on the values equal to or smaller than the threshold value (control factor) calculated in step S804 of FIG. 8. For example, in the first embodiment, the values surrounded by the solid lines are set to “0.” However, according to the third embodiment, a value of the area where the hatched range and the bold line range are overlapped is not set to “0,” but remains in its original value. As a result, the edges of the spanning tree are held. Therefore, it is possible to prevent disjointing of the graph that may cause an accuracy failure.

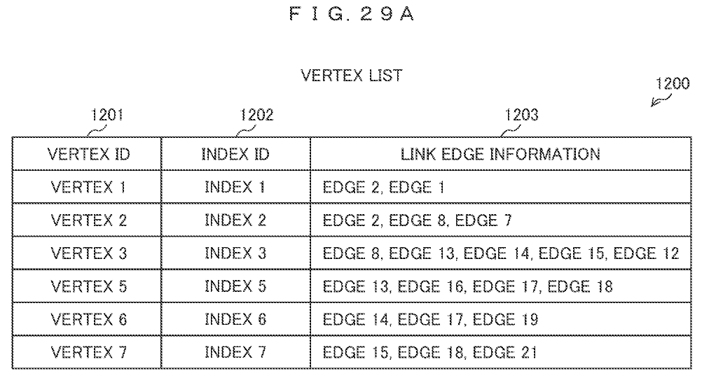

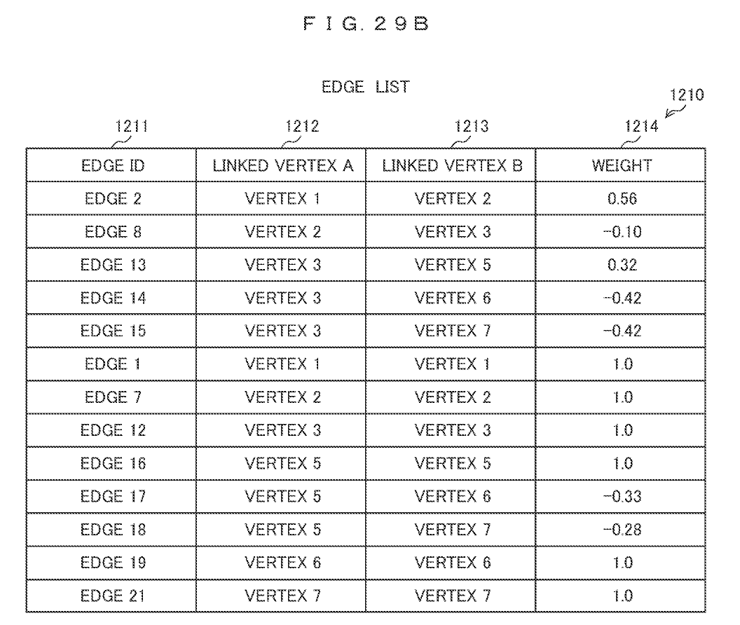

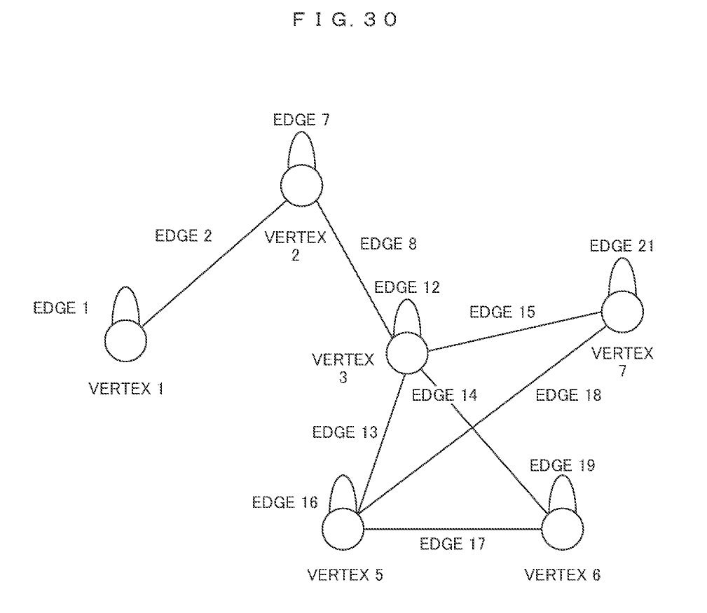

FIGS. 29A and 29B are explanatory diagrams illustrating the vertex list 1200 and the edge list 1210 after the graph data creation process according to the third embodiment of the present invention is executed. FIG. 30 is an explanatory diagram illustrating an exemplary graph displayed on the basis of the graph data according to the third embodiment of the present invention.

FIG. 31 is a flowchart illustrating an exemplary graph data creation process (step S2202) according to the third embodiment.

The graph data creating section 113 acquires the vertex list 1200 and the edge list 1210 output from the spanning tree creating section 116, and the edge candidate list 2601 held as intermediate data (step S2801). The edge candidate list 2601 subjected to the spanning tree creation process stores a list of the edges of the spanning tree deleted from the edge candidate list 2601 before the spanning tree creation process.

The graph data creating section 113 calculates the number of addable edges by subtracting the number of edges of the spanning tree included in the edge candidate list from the maximum number of edges calculated by the control factor calculation section 112 (S2802). In addition, the edges of the edge candidate list 2601 are selected and read within a range of the number of addable edges (S2803).

For example, until the number of addable edges, the edges are selected sequentially in descending order from the highest edge weight in the edge candidate list 2601. In addition, instead of selecting the edges sequentially in descending order from the largest weight until the number of addable edges, for example, the edges may be randomly sampled from the edge candidate list until the number of addable edges. In this case, weighted sampling may be performed to select the edge having the higher weight with a higher priority (upper layer element in the edge candidate list). In order to prevent an element having the lower weight from being acquired, a threshold value may be set (if the sampled edge is equal to or smaller than the threshold value, it will not be added).

The graph data creating section 113 adds the selected edge to the edge list 1201, updates the vertex list 1200 (S2805), and outputs the graph data (S2805).

Here, since a process of creating the graph data using the edge candidate list created for the spanning tree creation process has been described, the maximum number of edges is used as the control factor. Alternatively, in a similar manner to the first or second embodiment, the threshold value of the element calculated on the basis of the maximum number of edges may be used as the control factor. In this case, as illustrated in FIG. 28, elements of the spanning tree and elements determined on the basis of the threshold value serving as the control factor are selected from the correlation matrix data, and these elements are used to create the graph data.

If the graph data creation process is terminated, the vertex list 1200 and the edge list 1210 have the states illustrated in FIGS. 14A and 14B. The graph data creating section 113 outputs the vertex list 1200 and the edge list 1210 to the graph data storing section 115 and transmits them to the user terminal 210. The user terminal 210 may display the graph of FIG. 30 on the basis of the received graph data.

According to the third embodiment, it is possible to create graph data in which a spanning tree structure is held such that at least one side of overall useful nodes is connected to the other node. That is, according to the third embodiment, it is possible to prevent graph disjointing by which a graph that may cause an accuracy failure is divided into a plurality of link components. Therefore, it is possible to hold a spanning tree structure in the graph data to be created and perform a graph processing while maintaining necessary accuracy.

Note that the present invention is not limited to the aforementioned embodiments, and various modifications may also be possible. For example, while the configurations have been described in details for the aforementioned embodiments for convenient description purposes, it is not necessary to provide overall components of the configurations described above to embody the present invention. In addition, any addition, deletion, or substitution may also be possible for a part of the configuration of each embodiment.

In addition, each of the aforementioned configurations, functions, processing units, processing means, and the like may be realized by hardware, for example, by designing some or all of them with, for example, an integrated circuit. Furthermore, the present invention can be realized by a program code of software that realizes the functions of the embodiments. In this case, a storage medium storing the program code is provided to the computer, and a processor included in the computer reads the program code stored in the storage medium. In this case, the program code itself read from the storage medium realizes the functions of the aforementioned embodiments, and the program code itself and the storage medium storing the program code constitute the present invention. Examples of the storage medium for supplying such program code may include a flexible disk, a compact disc read-only memory (CD-ROM), a digital versatile disc ROM (DVD-ROM), a hard disk, an solid state drive(SSD), an optical disk, a magneto-optical disk, a CD-recordable (CD-R), a magnetic tape, a nonvolatile memory card, a ROM, or the like.

In addition, the program code for realizing the functions described in this embodiment can be implemented in a wide range of programs or script languages such as assembler, C/C++, Perl, Shell, PHP, or Java (registered trademark).

Furthermore, by transmitting the program code of the software for realizing the functions of the embodiment via a network, the program code may be stored in a storage means such as a hard disk or a memory of a computer or a storage medium such as a CD-RW or a CD-R, and the processor included in the computer may read and execute the program code stored in the storage means or the storage medium.

In the aforementioned embodiments, the control lines or the information lines indicate those considered to be necessary for the explanation, and all of the control lines and information lines are not necessarily illustrated on the product. All the configurations may also be connected to each other.

1. A computer provided with a processor and a memory connected to the processor and configured to execute a processing using correlation matrix data having correlation values between a plurality of indices as elements, the computer comprising:
a graph processing unit configured to create first graph data having a list structure provided with a vertex corresponding to a single index, an edge that links a pair of the vertices having a correlation, and an edge weight as a value of the element from the correlation matrix data acquired from a storage unit,
the graph processing unit having
a control factor calculation section configured to calculate a maximum number of edges that can be contained in the first graph data in order to complete the processing using the correlation matrix data within a predetermined time,
a spanning tree creating section configured to convert the correlation matrix data into second graph data having a list structure and create third graph data as a spanning tree provided with all vertices and a part of the edges of the second graph data, and
a graph data creating section configured to create the first graph data on the basis of the second and third graph data using the maximum number of edges.

2. The computer according to claim 1, wherein the spanning tree is a maximum spanning tree in which a sum of the edge weights is maximized.

3. The computer according to claim 2, wherein the first graph data contains the third graph data.

4. The computer according to claim 3, wherein the graph data creating section creates the first graph data by adding the edges included in only the second graph data to the third graph data in order of the weight until a total number of the edges becomes the maximum number of edges.

5. The computer according to claim 1, wherein the spanning tree creating section deletes, from the correlation matrix data, an element of an index having a correlation value with all other indices equal to or smaller than a predetermined value out of the indices included in the correlation matrix data and converts the correlation matrix data having the deleted element of the index into the second graph data having a list structure.

6. A computer provided with a processor, and a memory and a storage unit connected to the processor to create graph data provided with a vertex corresponding to a single index, an edge that links a pair of the vertices having a correlation, and an edge weight as a value of an element, from the correlation matrix data containing correlation values between a plurality of the indices as elements,
the computer comprising a graph processing unit configured to acquire the correlation matrix data from the storage unit, detects elements of a spanning tree formed by linking vertices corresponding to the indices contained in the acquired correlation matrix data and an element having a value equal to or greater than a predetermined threshold value, and create the graph data from the detected elements.

7. A method of creating graph data in a computer provided with a processor and a memory connected to the processor and configured to execute a processing using correlation matrix data consisting of correlation values between a plurality of indices as elements,
the computer having a graph processing unit configured to create first graph data having a list structure provided with a vertex corresponding to a single index, an edge that links a pair of the vertices having a correlation, and an edge weight as a value of the element from the correlation matrix data acquired from a storage unit,
the graph processing unit performs:
calculating a maximum number of edges that can be contained in the first graph data in order to complete the processing using the correlation matrix data within a predetermined time,
converting the correlation matrix data into second graph data having a list structure and create third graph data as a spanning tree provided with all vertices and a part of the edges of the second graph data, and
creating the first graph data on the basis of the second and third graph data using the maximum number of edges.

8. The method of creating graph data according to claim 7, wherein the spanning tree is a maximum spanning tree in which a sum of the edge weights is maximized.

9. The method of creating graph data according to claim 8, wherein the seventh graph data contains the third graph data.

10. The method of creating graph data according to claim 9, wherein the first graph data is created by adding the edges included only in the second graph data to the third graph data in order of the weight until a total number of edges reaches the maximum number of edges.

11. The method of creating graph data according to claim 7, wherein an element of an index having a correlation value with all other indices equal to or smaller than a predetermined value out of the indices included in the correlation matrix data is deleted from the correlation matrix data, and
the correlation matrix data having the deleted element of the index is converted into the second graph data having a list structure.

12. A method of creating graph data in a computer provided with a processor, and a memory and a storage unit connected to the processor, and configured to create graph data provided with a vertex corresponding to a single index, an edge that links a pair of the vertices having a correlation, and an edge weight as a value of the element from correlation matrix data having correlation values between a plurality of indices as elements, the method comprising:
acquiring the correlation matrix data from the storage unit;
detecting elements of a spanning tree formed by linking vertices corresponding to indices included in the acquired correlation matrix data and an element having a value equal to or greater than a predetermined threshold value; and
creating the graph data on the basis of the detected elements.
